(19) United States
(12) Patent Application Publication
(10) Pub. No.: US 2016/0099397 A1
(43) Pub. Date: Apr. 7, 2016

(54) COMPOSITION FOR FORMING THERMOELECTRIC CONVERSION LAYER, THERMOELECTRIC CONVERSION ELEMENT, AND THERMOELECTRIC POWER GENERATING COMPONENT

(71) Applicant: FUJIFILM Corporation, Tokyo (JP)

(72) Inventors: Yoichi MARUYAMA, Ashigara-kami-gun (JP); Takeyoshi KANO, Ashigara-kami-gun (JP)

(73) Assignee: FUJIFILM Corporation, Tokyo (JP)

(21) Appl. No.: 14/971,635

(22) Filed: Dec. 16, 2015

Related U.S. Application Data
(63) Continuation of application No. PCT/JP2014/064599, filed on Jun. 2, 2014.

(30) Foreign Application Priority Data
Jun. 24, 2013 (JP) 2013-131784
Oct. 2, 2013 (JP) 2013-207292

(51) Int. Cl. H01L 35/24

(52) U.S. Cl. CPC H01L 35/24

(57) ABSTRACT

Provided are a composition for forming a thermoelectric conversion layer, the composition having excellent thermoelectric characteristics; a thermoelectric conversion element, in which the composition is used to form a thermoelectric conversion layer; and a thermoelectric power generating component. The composition for forming a thermoelectric conversion layer includes inorganic particles having an average particle size of 1.0 μm or less; a carrier transport material which satisfies at least one of the condition that the mobility is 0.001 cm²/Vs or more and the condition that the carrier density is 1×10¹⁰ cm⁻³ to 1×10²¹ cm⁻³ when the band gap of the inorganic particles is 1.5 eV or less; and a material for a thermal excitation source which is an organic material satisfying the condition that the band gap is 1.5 eV or less when the band gap of the inorganic particles is more than 1.5 eV.

### CROSS-REFERENCE TO RELATED APPLICATIONS

This application is a Continuation of PCT International Application No. PCT/JP2014/064599 filed on Jun. 2, 2014, which claims priority under 35 U.S.C. §119(a) to Japanese Patent Application No. 2013-131784 filed on Jun. 24, 2013 and Japanese Patent Application No. 2013-207292 filed on Oct. 2, 2013. Each of the above application(s) is hereby expressly incorporated by reference, in its entirety, into the present application.

### BACKGROUND OF THE INVENTION

1. Field of the Invention

The present invention relates to a composition for forming a thermoelectric conversion layer, a thermoelectric conversion element which uses the composition for the formation of a thermoelectric conversion layer, and a thermoelectric power generating component.

2. Description of the Related Art

Thermoelectric conversion materials that can mutually convert heat energy and electric energy are used in thermoelectric power generating elements and thermoelectric conversion elements such as Peltier devices.

Thermoelectric power generation achieved by applying such thermoelectric conversion materials or thermoelectric conversion elements enables direct conversion from heat energy to electric power, does not require any moving parts, and is used in wrist watches that are operated by body temperature, as well as power supplies for remote areas and power supplies used in space.

The figure of merit Z of a thermoelectric conversion material is represented by the following Formula (A), and an important factor for performance enhancement is the increase in the thermopower S and electrical conductivity a.

<Figure of Merit>

Figure of merit ZT=S²·σ·T/κ (A)
S (V/K): Thermopower (Seebeck coefficient)
σ (S/m): Electrical conductivity
κ (W/mK): Thermal conductivity
T (K): Absolute temperature

Regarding such a thermoelectric conversion material or a material used for a thermoelectric conversion element, WO2012/133314 describes “an electroconductive composition including (A) carbon nanotubes, (B) an electroconductive polymer, and (C) an onium salt compound.”

Also, JP2013-095820A describes “an electroconductive composition including (A) carbon nanotubes, (B) an electroconductive polymer, (C) an onium salt compound, and (D) a polymerizable compound.”

Furthermore, JP2013-095821A describes “an electroconductive composition including (A) carbon nanotubes, (B) an electroconductive polymer, and (C) a compound which generates a radical when irradiated with active energy radiation or exposed to heat.”

In addition, JP2013-098299A describes “a thermoelectric conversion material including an electroconductive polymer, carbon nanotubes and an onium salt compound, and having an electrical conductivity anisotropy of 1.5 to 10.”

### SUMMARY OF THE INVENTION

However, the inventors of the present invention investigated the possibility of amelioration of the thermoelectric conversion materials and the like described in Patent Documents 1 to 4, and the inventors found that there still is room for a further improvement in the thermopower S (hereinafter, also referred to as “thermoelectric characteristics”).

Thus, an object of the invention is to provide a composition for forming a thermoelectric conversion layer having excellent thermoelectric characteristics, and a thermoelectric conversion element which uses the composition for forming a thermoelectric conversion layer for the formation of a thermoelectric conversion layer, and a thermoelectric power generating component.

The present inventors conducted a thorough investigation in order to solve the problems described above, and as a result, the inventors found that when inorganic particles having an average particle size of 1.0 μm or less are included, and when a material for carrier transport which satisfies at least one of the condition that the mobility is 0.001 cm²/Vs or more and the condition that the carrier density is 1×10¹⁰ cm⁻³ to 1×10²¹ cm⁻³, depending on the value of the band gap of the inorganic particles, or a material for a thermal excitation source which satisfies the condition that the band gap is 1.5 eV or less, depending on the value of the band gap of the inorganic particles, is included, a thermoelectric conversion element and a thermoelectric power generating component having excellent thermoelectric characteristics can be produced. Thus, the inventors completed the present invention.

That is, the present inventors found that the problems described above can be solved by the following configurations.

(1) A composition for forming a thermoelectric conversion layer including inorganic particles having an average particle size of 1.0 μm or less; a carrier transport material which satisfies at least one of the condition that the mobility is 0.001 cm²/Vs or more and the condition that the carrier density is 1×10¹⁰ cm⁻³ to 1×10²¹ cm⁻³ when the band gap of the inorganic particles is 1.5 eV or less; and a material for a thermal excitation source which is an organic material satisfying the condition that the band gap is 1.5 eV or less when the band gap of the inorganic particles is more than 1.5 eV.

(2) The composition for forming a thermoelectric conversion layer according to (1), in which the band gap of the inorganic particles is 1.5 eV or less, and the material for carrier transport includes at least one of an electroconductive nanomaterial and an electroconductive polymer material.

(3) A composition for forming a thermoelectric conversion layer according to (2), in which the material for carrier transport includes both an electroconductive nanomaterial and an electroconductive polymer material.

(4) The composition for forming a thermoelectric conversion layer according to (2) or (3), in which the electroconductive nanomaterial is a carbon nanomaterial or a metal nanomaterial.

(5) The composition for forming a thermoelectric conversion layer according to any one of (2) to (4), in which the electroconductive nanomaterial is at least one selected from the group consisting of carbon nanotubes, carbon nanofibers, graphite, graphene, carbon nanoparticles, and metal nanowires.

(6) The composition for forming a thermoelectric conversion layer according to any one of (2) to (5), in which the electroconductive nanomaterial is the carbon nanotubes.

(7) The composition for forming a thermoelectric conversion layer according to any one of (2) to (6), in which the material for carrier transport is an organic material.

(8) The composition for forming a thermoelectric conversion layer according to (1), in which the band gap of the inorganic particles is more than 1.5 eV, and the material for a thermal excitation source includes at least one selected from the group consisting of a carbon nanomaterial, an infrared absorbing dye, and an electroconductive polymer.

(9) The composition for forming a thermoelectric conversion layer according to (8), in which the electroconductive polymer is polythiophene or polyacetylene.

(10) The composition for forming a thermoelectric conversion layer according to any one of (1) to (9), in which the ratio between the number of particles having a particle size of 1.0 μm or less and the number of particles having a particle size of more than 1.0 μm (number of particles having a particle size of 1.0 μm or less/number of particles having a particle size of more than 1.0 μm) in the inorganic particles is 5 or more.

(11) The composition for forming a thermoelectric conversion layer according to any one of (1) to (10), further including a dopant.

(12) The composition for forming a thermoelectric conversion layer according to any one of (1) to (11), further including a non-conjugated polymer.

(13) A thermoelectric conversion element having a substrate, a pair of electrodes, and a thermoelectric conversion layer, in which the thermoelectric conversion layer is formed from the composition for forming a thermoelectric conversion layer according to any one of (1) to (12).

(14) A thermoelectric power generating component using the thermoelectric conversion element according to (13).

As will be described below, according to the invention, a composition for forming a thermoelectric conversion layer having excellent thermoelectric characteristics, a thermoelectric conversion element which uses the composition for the formation of a thermoelectric conversion layer, and a thermoelectric power generating component can be provided.

### BRIEF DESCRIPTION OF THE DRAWINGS

FIG. 1 is a cross-sectional diagram schematically illustrating an example of the thermoelectric conversion element of the invention. The avow in FIG. 1 indicates the direction of the temperature difference applied at the time of use of the element.

FIG. 2 is a cross-sectional diagram schematically illustrating an example of the thermoelectric conversion element of the invention. The arrow in FIG. 2 indicates the direction of the temperature difference applied at the time of use of the element.

FIG. 3 is a cross-sectional diagram schematically illustrating an example (module) of the thermoelectric conversion element of the invention.

### DESCRIPTION OF THE PREFERRED EMBODIMENTS

[Composition for Forming Thermoelectric Conversion Layer]

In the following, the composition for forming a thermoelectric conversion layer of the invention (hereinafter, also referred to as “composition of the invention”) will be described in detail.

First, technical features of the invention will be described in detail through a comparison with the prior art technologies.

The composition for forming a thermoelectric conversion layer according to a first embodiment of the invention includes inorganic particles having an average particle size of 1.0 μm or less, while the band gap of these inorganic particles is 1.5 eV or less, and the composition includes a material for carrier transport which satisfies at least one of the condition that the mobility is 0.001 cm²/Vs or more and the condition that the carrier density is 1×10¹⁰ cm⁻³ to 1×10²¹ cm⁻³.

Meanwhile, a numerical value range described using “to” in the present specification means a range including the values described before and after “to” as the lower limit value and the upper limit value.

The inventors of the present invention speculate the reason why the effects of the invention are obtained in the first embodiment, as follows. However, the scope of the invention should not be construed to be limited by this speculation.

That is, it is speculated that when inorganic particles having an average particle size of 1.0 μm or less are incorporated, thermally excited carriers are formed also from the inorganic particles in the thermoelectric conversion layer, and consequently, the thermoelectric conversion efficiency is increased, while the thermoelectric characteristics are improved.

At this time, since the band gap of the inorganic particles is 1.5 eV or less, it is considered that the inorganic particles more suitably function mainly as a thermal excitation source. Therefore, it is thought that when the inorganic particles are combined with a material which satisfies at least one of the condition that the mobility is 0.001 cm²/Vs or more and the condition that the carrier density is 1×10¹⁰ cm⁻³ to 1×10²¹ cm⁻³, as a material for transporting the carriers thus generated, the generated carriers can be transported more suitably, and the thermoelectric characteristics are improved.

Next, the composition for forming a thermoelectric conversion layer according to a second embodiment of the invention includes inorganic particles having an average particle size of 1.0 μm or less, while the band gap of these inorganic particles is more than 1.5 eV, and the composition includes a material for a thermal excitation source, which satisfies the condition that the band gap is 1.5 eV or less.

The present inventors speculate the reason why the effects of the invention are obtained in the second embodiment, as follows. However, the scope of the invention should not be construed to be limited by this speculation.

That is, it is speculated that since the inorganic particles have high electrical conductivity, in a case in which the band gap of the inorganic particles is more than 1.5 eV, the inorganic particles mainly function as a transporter of carriers when the inorganic particles are combined with a material which satisfies the condition that the band gap is 1.5 eV or less. Therefore, it is considered that when the inorganic particles are combined with a material which is suitable as a material that excites carriers and satisfies the condition that the band gap is 1.5 eV or less, the carriers can be excited and transported more suitably, and thus the thermoelectric characteristics are improved.

Furthermore, the effects of the invention are effects that are not manifested in Comparative Example 1 which will be described below, in which inorganic particles having an average particle size of 1.1 μm are incorporated, and therefore, it is understood that the effects are extremely surprising effects. From these results, it is considered that when the average particle size of the inorganic particles is 1.0 μm or less, thermal conductivity which is one of the characteristics contributing to the thermoelectric performance, that is, κ (W/mK) in the Formula (A) described above, has greatly decreased.

Next, the various components of the compositions of the first embodiment and the second embodiment of the invention (hereinafter, may be collectively referred to as “composition of the invention”) are described in detail, and thereafter, the thermoelectric conversion element having a thermoelectric conversion layer formed using the composition of the invention and a thermoelectric power generating component are described in detail.

<Inorganic Particles>

The inorganic particles included in the composition of the invention are inorganic particles having an average particle size of 1.0 μm or less.

Here, the average particle size refers to an average particle size determined according to a dynamic light scattering method.

According to the invention, as described above, satisfactory thermoelectric characteristics are obtained by using inorganic particles having an average particle size of 1.0 μm or less. Meanwhile, as disclosed in the Examples which will be described below, a dynamic light scattering type particle size/particle size distribution analyzer (Nanotrac UPA-EX150, manufactured by Nikkiso Co., Ltd.) was used for the measurement of the average particle size or the number of particles described below.

Furthermore, due to the reason that the thermoelectric characteristics become more satisfactory, it is preferable that the average particle size of the inorganic particles is 1 nm to 0.9 μm, more preferably 5 nm to 0.8 μm, and particularly preferably 10 nm to 0.7 μm.

According to the invention, it is preferable that the ratio between the number of particles having a particle size of 1.0 μm or less and the number of particles having a particle size of more than 1.0 μm (number of particles having a particle size of 1.0 μm or less/number of particles having a particle size of more than 1.0 μm) (hereinafter, also briefly referred to as “ratio of the number of particles”) in connection with the inorganic particles is 5 or more, and more preferably 7 to 100.

When the ratio of the number of particles is 5 or more, the thermoelectric characteristics become more satisfactory. This is speculated to be because there are relatively fewer particles having large particle sizes, and the thermal conductivity is decreased.

Here, the number of particles having a particle size of 1.0 μm or less and the number of particles having a particle size of more than 1.0 μm refer to values calculated from a frequency distribution determined according to a dynamic light scattering method.

Regarding such inorganic particles, as long as a thermoelectric conversion material having an average particle size of 1.0 μm or less is used, there are no particular limitations on the material.

Here, regarding the inorganic particles having a band gap of 1.5 eV or less that are used for the first embodiment, any material appropriately selected from, for example, a Bi—Te-based material, a Bi—Se-based material, a Sb—Te-based material, a Pb—Te-based material, a Ge—Te-based material, a Bi—Sb-based material, a Zn—Sb-based material, a Sn—Te-based material, a Co—Sb-based material, a Ag—Sb—Te-based material, a Si—Ge-based material, an Fe—Si-based material, a Mg—Si-based material, a Mn—Si-based material, a Na—Co—O-based material, a Ti—Sr—O-based material, a Bi—Sr—Co—O-based material, Si, Ge, an In—P-based material, an In—N-based material, and a Ga—As-based material, can be used.

Furthermore, regarding the inorganic material having a band gap of more than 1.5 eV that is used for the second embodiment, any material appropriately selected from, for example, a Ga—P-based material, an Al—Sb-based material, an Al—N-based material, a Ga—N-based material, a Si—C-based material, a Zn—O-based material, an In—Ga—Zn—O-based material, and a Ti—O-based material, can be used.

Here, according to the invention, the band gap is calculated by the following Calculation Formula (1) from an absorption edge measured using an ultraviolet/visible spectrophotometer:

E(Bg)=hc/eλ (eV) Formula (1)

where h=6.6×10⁻³⁴ (Js): Planck's constant, e=1.6×10⁻¹⁹ (C): charge of an electron, c=3.0×10⁸ (m/s): speed of light, and λ (nm): wavelength of light.

According to the invention, the content of the inorganic particles is preferably 1 wt % to 90 wt %, and more preferably 10 wt % to 80 wt %, relative to the total solid content of the composition.

<Material for Carrier Transport>

The material for carrier transport that is included in the composition of the first embodiment of the invention is a material which satisfies at least one of the condition that the mobility is 0.001 cm²/Vs or more and the condition that the carrier density is 1×10¹⁰ cm⁻³ to 1×10²¹ cm⁻³.

The material for carrier transport is not particularly limited as long as the material satisfies the conditions described above; however, examples thereof include an electroconductive nanomaterial, an electroconductive polymer material, and a low molecular weight type organic semiconductor. These may be used in combination.

Here, it is preferable to use an organic material as the material for carrier transport. Thereby, the thermoelectric characteristics can be further enhanced.

Inorganic particles have high electrical conductivity; however, when inorganic particles are used alone, the contact area between the inorganic particles is small, and it is difficult to exhibit high electrical conductivity. In this regard, it is speculated that when a material for carrier transport is used as an organic material, and the spaces between the inorganic particles having high electrical conductivity are filled with the organic material, high electrical conductivity can be exhibited, and also, a balance between high electrical conductivity and high electromotive force can also be achieved by using a low band gap inorganic material.

Furthermore, it is preferable to use an electroconductive nanomaterial and an electroconductive polymer material in combination as the material for carrier transport.

When an electroconductive nanomaterial and an electroconductive polymer are included, the electroconductive nanomaterial (particularly CNT) is uniformly dispersed in the composition without aggregating, and thus coatability of the composition is enhanced. Furthermore, a composition having high electrical conductivity is obtained. This is speculated to be because, since the electroconductive polymer has a stretched conjugated structure, the charge transfer between the electroconductive polymer and the electroconductive nanomaterial becomes smooth, and consequently, the high electrical conductivity and semiconductor characteristics of the electroconductive nanomaterial can be effectively utilized.

(Electroconductive Nanomaterial)

The electroconductive nanomaterial used as the material for carrier transport is not particularly limited as long as the material satisfies the conditions described above, and any conventionally known carbon nanomaterial (carbon-containing electroconductive nanomaterial) or metal nanomaterial (metal-containing electroconductive nanomaterial) can be used. Meanwhile, according to the invention, the electroconductive nanomaterial is a class of material which does not include electroconductive polymers that will be described below.

Here, regarding the electrical conductivity of the electroconductive nanomaterial, it is preferable that the specific resistance is 8×10⁻³ Ω·cm or less.

Furthermore, the size of the electroconductive nanomaterial is not particularly limited as long as the material is nano-sized (less than 1 μm); however, for example, in regard to the carbon nanotubes, carbon nanofibers, metal nanowires and the like that are described below, it is desirable that the average minor axis is nano-sized (for example, the average minor axis is 500 nm or less).

Specific examples of the electroconductive nanomaterial include carbon nanotubes (hereinafter, also referred to as “CNT”), carbon nanofibers, graphite, graphene, carbon nanoparticles, and metal nanowires, and these may be used singly or in combination of two or more kinds thereof.

Among these, the electroconductive nanomaterial is preferably CNT, for the reason that more satisfactory thermoelectric characteristics are obtained.

Furthermore, regarding the CNT, for example, those described in paragraphs “0017” to “0021” of WO2012/133314 and paragraphs “0018” to “0022” of JP2013-095820A can be appropriately employed.

The content of the electroconductive nanomaterial in the composition of the invention is preferably 2% by mass to 60% by mass, more preferably 5% by mass to 55% by mass, and particularly preferably 10% by mass to 50% by mass, relative to the total solid content of the composition.

(Electroconductive Polymer)

The electroconductive polymer used as the material for carrier transport is not particularly limited as long as the polymer satisfies the conditions described above, and any conventionally known electroconductive polymer can be used.

The term electroconductive polymer refers to a polymer compound having a conjugated molecular structure, and specifically refers to a polymer having a structure in which, regarding the carbon-carbon bonds in the main chain of the polymer, single bonds and double bonds are alternately arranged. Also, the electroconductive polymer used for the invention is not necessarily a macromolecular compound, and may be an oligomer compound.

Examples of the electroconductive polymer include conjugated polymers which use, as monomers, a thiophene-based compound, a pyrrole-based compound, an aniline-based compound, an acetylene-based compound, a p-phenylene-based compound, a p-phenylene vinylene-based compound, a p-phenylene ethynylene-based compound, a p-fluorenylene vinylene-based compound, a polyacene-based compound, a polyphenanthrene-based compound, a metal phthalocyanine-based compound, a p-xylylene-based compound, a vinylene sulfide-based compound, a m-phenylene-based compound, a naphthalene vinylene-based compound, a p-phenylene oxide-based compound, a phenylene sulfide-based compound, a furan-based compound, a selenophene-based compound, an azo-based compound, a metal complex-based compound, and derivatives obtained by introducing substituents to these compounds, and which have repeating units derived from the relevant monomers.

Regarding such an electroconductive polymer, for example, those described in paragraphs “0022” to “0052” of WO2012/133314 and paragraphs “0023” to “0053” of JP2013-095820A can be appropriately employed.

(Low Molecular Weight Type Organic Semiconductor)

The low molecular weight type organic semiconductor used as the material for carrier transport is not particularly limited as long as the material satisfies the conditions described above, and any conventionally known low molecular weight type organic semiconductor can be used.

Regarding the low molecular weight type organic semiconductor used as the material for carrier transport, for example, an acene such as tetracene, pentacene or TIPS pentacene; a phthalocyanine, a perylene derivative, rubrene, or a thienoacene such as benzothienobenzothiophene or dinaphthothienothiophene, can be used.

<Material for Thermal Excitation Source>

The material for a thermal excitation source included in the composition of the second embodiment of the invention is an organic material which satisfies the condition that the band gap is 1.5 eV or less.

The material for a thermal excitation source is not particularly limited as long as the material satisfies the condition described above; however, examples thereof include a carbon nanomaterial, an infrared absorbing dye, and an electroconductive polymer, and these may be used in combination.

The content of the material for a thermal excitation source in the composition of the second embodiment of the invention is preferably 1 part by mass to 90 parts by mass, and more preferably 10 parts by mass to 80 parts by mass, relative to the total solid content of the composition.

(Carbon Nanomaterial)

The carbon nanomaterial used as the material for a thermal excitation source is not particularly limited as long as the nanomaterial satisfies the condition described above, and any conventionally known carbon nanomaterial can be used. Specifically, the carbon nanomaterials such as carbon nanotubes and carbon nanofibers described as examples of the material for carrier transport for the composition of the first embodiment can be used.

(Infrared Absorbing Dye)

The infrared absorbing dye used as the material for a thermal excitation source is not particularly limited as long as the dye satisfies the condition described above, and any conventionally known infrared absorbing dye can be used.

Examples of the infrared absorbing dye include a metal complex, a charge-transfer complex, and an arylamine compound.

(Metal Complex)

The central metal of the metal complex is preferably a metal atom selected from the group consisting of Ni, Fe, Cu and Sn, or a metal ion thereof

The atoms coordinating the central metal are preferably heteroatoms, and a sulfur atom, an oxygen atom or a nitrogen atom is more preferred. Also, it is preferable that among the atoms coordinating the central metal, at least one of them is a sulfur atom or an oxygen atom.

The metal complex used for the invention is preferably a metal complex represented by the following Formula (3).

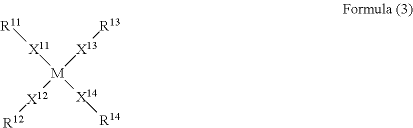

In Formula (3), M represents a metal atom selected from the group consisting of Ni, Fe, Cu and Sn, or a metal ion thereof; when M represents a metal ion, the metal ion may have an optional counterion; X¹¹, X¹², X¹³ and X¹⁴ each independently represent a heteroatom, and at least one of X¹¹ to X¹⁴ represents a sulfur atom or an oxygen atom; R¹¹, R¹², R¹³ and R¹⁴ each independently represent a substituent; and R¹¹ with R¹², and R¹³ with R¹⁴ may be bonded to each other.

The heteroatoms of X¹¹ to X¹⁴ are preferably a sulfur atom, an oxygen atom or a nitrogen atom.

Examples of the substituent for R¹¹ to R¹⁴ include an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, or a pentadecyl group); a cycloalkyl group (for example, a cyclopentyl group or a cyclohexyl group), an alkenyl group (for example, a vinyl group or an allyl group), an alkynyl group (for example, an ethynyl group or a propargyl group), an aromatic hydrocarbon ring group (also referred to as an aromatic carbon ring group, an aryl group or the like; for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, or a biphenylyl group), an aromatic heterocyclic group (a 5-membered or 6-membered aromatic heterocyclic group is preferred, and the ring-constituting heteroatom is preferably a sulfur atom, a nitrogen atom, an oxygen atom, a silicon atom, boron, or a selenium atom; for example, a pyridyl group, a pyrimidinyl group, a furyl group, a pyrrolyl group, an imidazolyl group, a benzimidazolyl group, a pyrazolyl group, a pyrazinyl group, a triazolyl group (for example, a 1,2,4-triazol-1-yl group or a 1,2,3-triazol-1-yl group), an oxazolyl group, a benzoxazolyl group, a thiazolyl group, an isoxazolyl group, an isothiazolyl group, a furazanyl group, a thienyl group, a quinolyl group, a benzofuryl group, a dibenzofuryl group, a benzothienyl group, a dibenzothienyl group, an indolyl group, a carbazolyl group, a carbolinyl group, a diazacarbazolyl group (this represents a group in which one of the carbon atoms constituting the carboline ring of the carbolinyl group is substituted by a nitrogen atom), a quinoxalinyl group, a pyridazinyl group, a triazinyl group, a quinazolinyl group, a phthalazinyl group, a borol group, or an azaborine group), a heterocyclic group (a non-aromatic heterocyclic group that may have a saturated ring or an unsaturated ring, and preferably has a 5-membered ring or a 6-membered ring, and the ring-constituting heteroatom is preferably a sulfur atom, a nitrogen atom, an oxygen atom, a silicon atom, or a selenium atom; examples include a pyrrolidyl group, an imidazolidyl group, a morpholyl group, or an oxazolidyl group), an alkoxy group (for example, a methoxy group, an ethoxy group, a propyloxy group, a pentyloxy group, a hexyloxy group, an octyloxy group, or a dodecyloxy group), a cycloalkoxy group (for example, a cyclopentyloxy group or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group),

an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, an acryloyl group, a methacryloyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecylcarbonyloxy group, or a phenylcarbonyloxy group), an amide group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylaminoureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group or a heteroarylsulfonyl group (for example, a phenylsulfonyl group, a naphthylsulfonyl group, or a 2-pyridylsulfonyl group), an amino group (including an amino group, an alkylamino group, an arylamino group, and a heterocyclic amino group; and for example, an amino group, an ethylamino group, a dimethylamino group, a butylamino group, a cyclopentylamino group, a 2-ethylhexylamino group, a dodecylamino group, an anilino group, a naphthylamino group, or a 2-pyridylamino group), a cyano group, a nitro group, a hydroxy group, a mercapto group, and a silyl group (for example, a trimethylsilyl group, a triisopropylsilyl group, a triphenylsilyl group, or a phenyldiethylsilyl group).

Among them, preferred examples include an aromatic hydrocarbon ring group, an aromatic heterocyclic group, a heterocyclic group, an aryloxy group, an arylthio group, an aryloxycarbonyl group, a sulfamoyl group, an acyl group, an acyloxy group, an amide group, and a carbamoyl group.

The metal complex represented by Formula (3) is preferably a metal complex represented by any of the following Formulae (3A) to (3D):

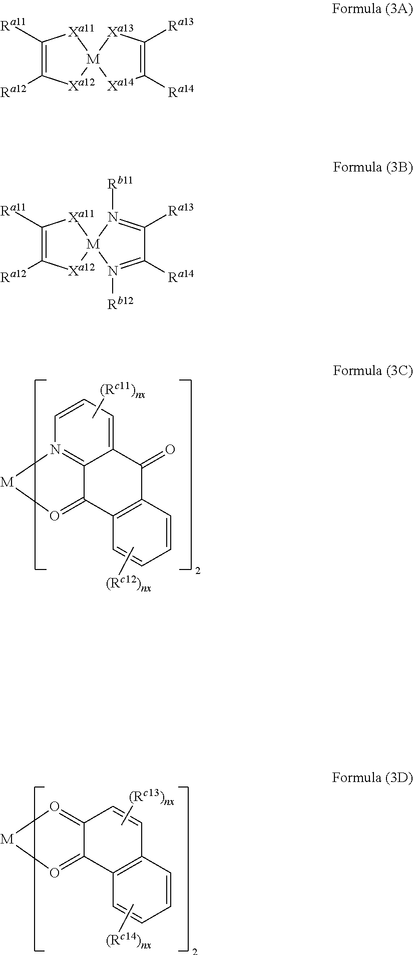

In Formulae (3A) to (3D), M has the same meaning as M in Formula (3), and a preferred range thereof is also the same. When M represents a metal ion, the metal ion may have an arbitrary counterion. to Xa¹¹ each independently represent —S— or —O—. Ra¹¹ to Ra¹⁴, Rb¹¹, and Rb¹² each independently represent a hydrogen atom or a substituent, and R¹¹ to Rc¹⁴ each independently represent a substituent. Here, with regard to Ra¹¹ to Ra¹⁴, Rb¹¹, Rb¹², and Rc¹¹ to Rc¹⁴, any two adjacent groups may be bonded to each other to form a ring. nx represents an integer of 0 or greater.

Examples of the substituent for Ra¹¹ to Ra¹⁴, Rb¹¹, Rb¹², and Rc¹¹ to Rc¹⁴ include the substituents for R¹¹ to R¹⁴ mentioned above. Rb¹¹ and Rb¹² are each preferably a hydrogen atom, an alkyl group or an aryl group.

Specific examples of the metal complex include the following; however, the invention is not intended to be limited to these.

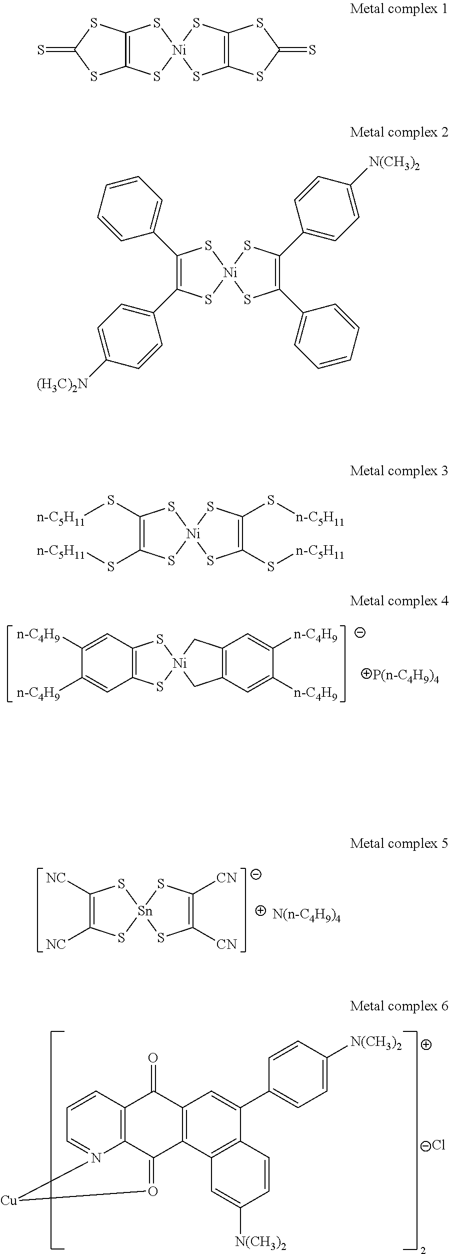

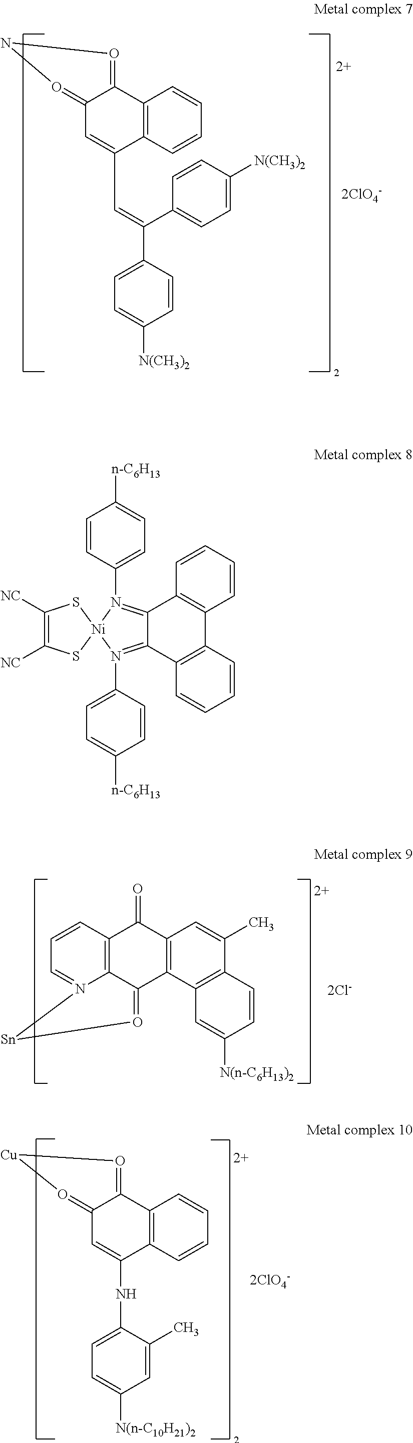

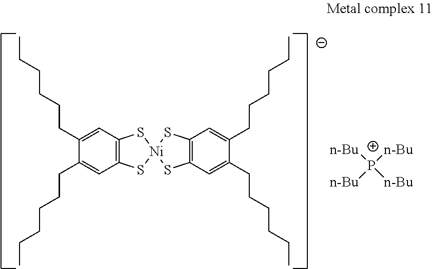

Regarding the metal complex used for the invention, a commercially available product can be used, or the metal complex may be chemically synthesized.

(Charge-Transfer Complex)

According to the invention, the term charge-transfer complex refers to an intermolecular compound composed of an electron donating molecule (electron donor) and an electron accepting molecule (electron acceptor), the compound exhibiting charge transfer interaction.

The charge transfer theory based on the molecular orbital theory has been defined by R. S. Mulliken. When the amount of charge transfer made by a complex D··A composed of an electron donor D and an electron acceptor A is represented by δ, the following formula is established, and a new absorption band (charge transfer absorption band) that is not exhibited by an electron donor or an electron acceptor alone appears on the longer wavelength side. Also, as the electron affinity of the electron acceptor becomes larger, the wavelength of the maximum absorption is shifted toward the longer wavelength side.

D+A⇄D^{+δ}··A^{-δ} 0≦δ≦1

The charge transfer complex used for the invention is an organic charge transfer complex composed of an organic electron donor and an organic electron acceptor. The relevant organic electron donor and organic electron acceptor are both neutral compounds that are not ionized or partially ionized before the donor and the acceptor form a complex, and when these are mixed and the molecules begin to approach, charge transfer occurs, and a complex is formed.

Furthermore, regarding the charge-transfer complex according to the invention, it is preferable that the intramolecular covalent bonds (any covalent bonds within the electron donor D, or any covalent bonds within the electron acceptor A) are not cleaved, that is, not degraded, even if the charge-transfer complex is irradiated with active energy radiation (for example, light or heat). Here, when it is said that an intramolecular covalent bond is not cleaved, it is implied that when the charge-transfer complex is irradiated with active energy radiation at a dose of from 0.5 J/cm² to 3.0 J/cm², the maximum absorption value of the absorption spectrum (maximum absorption of the charge transfer absorption band) does not change, or even if the maximum absorption value has changed, the maximum absorption value is reversibly restored by another external stimulation (for example, a change that is not accompanied by cleavage of a covalent bond, such as cis-trans steric isomerization, phase transition, or counter salt exchange).

An onium salt compound, which is one of the below-described dopants, is different from the charge-transfer complex from the viewpoint that both the electron donor and the electron acceptor are ionized and charged in a state before a salt is formed. Also, this onium salt is accompanied by chemical decomposition as the covalent bonds in the molecule are irreversibly cleaved when irradiated with active energy radiation. For example, in a sulfonium salt, the covalent bonds between the sulfur atom and the carbon atoms constituting a sulfonium cation are cleaved when irradiated with light, and a radical is generated. When it is said that covalent bonds in a molecule are irreversibly cleaved, it is implied that when the molecule is irradiated with active energy radiation at a dose of from 0.5 J/cm² to 3.0 J/cm², the maximum absorption value of the absorption spectrum changes irreversibly and is not restored to the original state.

When a charge-transfer complex is used as a material for a thermal excitation source, a thermoelectric conversion element having excellent temporal stability can be obtained.

As explained above, since thermoelectric conversion elements are used in wrist watches, power supplies for remote areas, power supplies used in space, and the like, the thermoelectric conversion elements are presumed to be used for a long time period in a high temperature and high humidity environment. Therefore, it is preferable that a thermoelectric conversion element has excellent initial thermoelectric conversion performance, and is also capable of maintaining the initial thermoelectric conversion performance for a long time period even in a high temperature and high humidity environment. When a charge-transfer complex is used, an element having high thermoelectric conversion performance and excellent temporal stability under high temperature and high humidity can be obtained.

The charge-transfer complex used for the invention, and the electron donor and electron acceptor constituting the complex may be any of low molecular weight compounds or high molecular weight compounds, and are preferably low molecular weight compounds. The weight average molecular weight of the charge-transfer complex is preferably 250 to 100,000, and more preferably 450 to 50,000. Furthermore, the weight average molecular weight of the electron donor is preferably 150 to 100,000, and more preferably 250 to 50,000. The weight average molecular weight of the electron acceptor is preferably 100 to 1200, and more preferably 120 to 800.

The weight average molecular weight can be measured by gel permeation chromatography (GPC). For example, gel permeation chromatography is carried out under the configuration and conditions of apparatus: “ALLIANCE GPC2000 (manufactured by Waters)”, column: TSKgel GMH6-HT×2+TSKgel GMH6-HTL×2 (all 7.5 mm I.D.×30 cm, manufactured by Tosoh Corporation), column temperature: 140° C., detector: differential refractometer, and mobile phase: solvent (for example, o-dichlorobenzene), and regarding the constitution of the molecular weight, the average molecular weight can be determined using polystyrene standards.

The electron donor that constitutes the charge-transfer complex of the invention is an organic compound capable of donating electrons, and does not contain any metal atom.

The organic electron donor is preferably a compound containing an aromatic ring structure. The relevant aromatic ring structure may be an aromatic hydrocarbon ring or an aromatic hetero ring, and the aromatic ring structure is preferably an aromatic hetero ring.

Here, the aromatic hydrocarbon ring may be a monocyclic hydrocarbon ring having aromaticity, and an example of the ring that constitutes the base is a benzene ring.

The aromatic hetero ring is not particularly limited as long as it is a monocyclic hetero ring having aromaticity, and a suitable example thereof is a 5-membered aromatic hetero ring or a 6-membered aromatic hetero ring. Examples of the heteroatom that constitutes the hetero ring include a sulfur atom, a nitrogen atom, an oxygen atom, a silicon atom, and a selenium atom, and a sulfur atom and a nitrogen atom are preferred, while a sulfur atom is more preferred. Examples of the 5-membered aromatic hetero ring include a thiophene ring, a furan ring, a pyrrole ring, a selenophene ring, a silole ring, an imidazole ring, a pyrazole ring, an oxazole ring, an isoxazole ring, a thiazole ring, an isothiazole ring, and a triazole ring. Examples of the 6-membered aromatic hetero ring include a pyridine ring, a pyrimidine ring, a pyridazine ring, a pyrazine ring, and a triazine ring. Among them, from the viewpoint of the thermoelectric conversion performance, a 5-membered aromatic hetero ring is more preferred, and a thiophene ring, a furan ring and a pyrrole ring are even more preferred, while a thiophene ring is particularly preferred.

It is preferable that the organic electron donor contains a fused ring structure. The ring that forms the fused ring may be an aliphatic ring or an aromatic ring, and may be a hydrocarbon ring or a hetero ring. Above all, a fused ring containing an aromatic ring structure is preferred, a fused ring containing an aromatic hetero ring structure is more preferred, and a fused ring of aromatic hetero rings, or a fused ring of an aromatic hydrocarbon ring and an aromatic hetero ring is even more preferred. Examples of the aromatic hydrocarbon ring and aromatic hetero ring that constitute the fused ring include the aromatic rings and aromatic hetero rings mentioned above, and preferred ranges thereof are also the same.

It is more preferable that the fused ring described above has a fused polycyclic structure in which three or more rings are fused, even more preferably a structure in which three or more rings including an aromatic ring are fused, and still more preferably a structure in which three or more rings selected from aromatic hydrocarbon rings and aromatic hetero rings are fused.

More preferred examples of the fused ring structure include a carbazole structure and a fluorene structure.

The ring structure included in the electron donor described above may have a substituent. Examples of the substituent include an alkyl group, an alkenyl group, an alkynyl group, an alkoxy group, an alkylthio group, and an amino group (including an alkylamino group and an arylamino group), and an alkyl group or an alkoxy group is preferred.

The alkyl group may be any of a linear, branched or cyclic group, and a linear alkyl group is preferred.

The number of carbon atoms of the alkyl group is preferably 1 to 20, and more preferably 1 to 10.

The alkyl moiety of the alkoxy group has the same meaning as the alkyl group mentioned above, and a preferred range thereof is also the same.

The alkyl moiety of the alkylthio group has the same meaning as the alkyl group mentioned above, and a preferred range thereof is also the same.

The amino group is preferably a mono- or dialkylamino group. The alkyl moiety of the alkylamino group has the same meaning as the alkyl group mentioned above, and a preferred range thereof is also the same.

The organic electron donor used for the invention is preferably a compound having a structure represented by the following Formula (1A) or (1B):

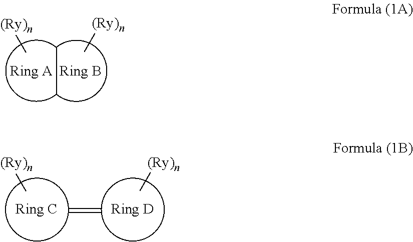

In Formulae (1A) and (1B), ring A represents an aromatic ring; ring B represents an aromatic ring, a non-aromatic hetero ring, or a non-aromatic hydrocarbon ring; ring C and ring D each represent a non-aromatic hetero ring or a non-aromatic hydrocarbon ring; Ry represents a substituent; and n represents an integer of 0 or greater.

Ring A to ring D may be each further fused with an aromatic ring, a non-aromatic hetero ring or a non-aromatic hydrocarbon ring.

The aromatic ring for the ring A and ring B has the same meaning as the aromatic ring (aromatic hydrocarbon ring and aromatic hetero ring) mentioned above, and a preferred range thereof is also the same.

The non-aromatic hetero ring for the rings B to D is preferably a 5-membered to 7-membered ring, and the ring-constituting heteroatom is preferably a sulfur atom, a nitrogen atom, an oxygen atom, a silicon atom, or a selenium atom. The non-aromatic hetero ring may be a saturated ring or an unsaturated ring (provided that the ring is not an aromatic ring).

The non-aromatic hydrocarbon ring for the rings B to D is preferably a 5-membered to 7-membered ring and may be a saturated ring or an unsaturated ring (provided that the ring is not an aromatic ring).

The rings A to D are each preferably a hetero ring, or a ring formed by hetero rings fused together.

When there are plural Ry's, the plural Ry's may be identical or different.

Ry is preferably an aromatic group (an aromatic hydrocarbon ring group and an aromatic heterocyclic group), an alkyl group, an alkenyl group, an alkynyl group, an alkoxy group, an alkylthio group, or an amino group (including an alkylamino group and an arylamino group). The aromatic group for Ry may be further substituted with an alkyl group, an alkenyl group, an alkynyl group, an alkoxy group, an alkylthio group, or an amino group (including an alkylamino group and an arylamino group).

The structure represented by Formula (1B) is even more preferably a structure represented by the following Formula (1B-1) or Formula (1B-2):

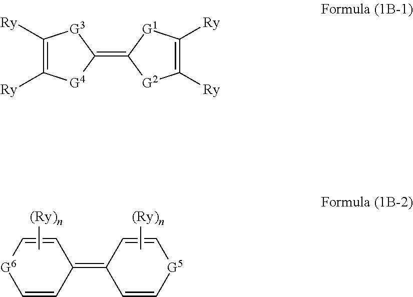

In Formulae (1B-1) and (1B-2), G1 to G4 each independently represent —S— or —Se—; and G5 and G6 each independently represent —S—, —N(Rx)— or —CH═CH—, where Rx represents a hydrogen atom or a substituent. Examples of the substituent include an alkyl group, an alkenyl group, an alkynyl group, and an alkoxy group. Rx is preferably a hydrogen atom.

In Formulae (1B-1) and (1B-2), Ry and n have the same meanings as Ry and n for Formula (1A) or (1B), respectively, and preferred ranges thereof are also the same.

Specific examples of the organic electron donor used for the invention are shown below; however, the invention is not intended to be limited to these. Meanwhile, in the following specific examples, the symbol * represents a linking site of a repeating structure.

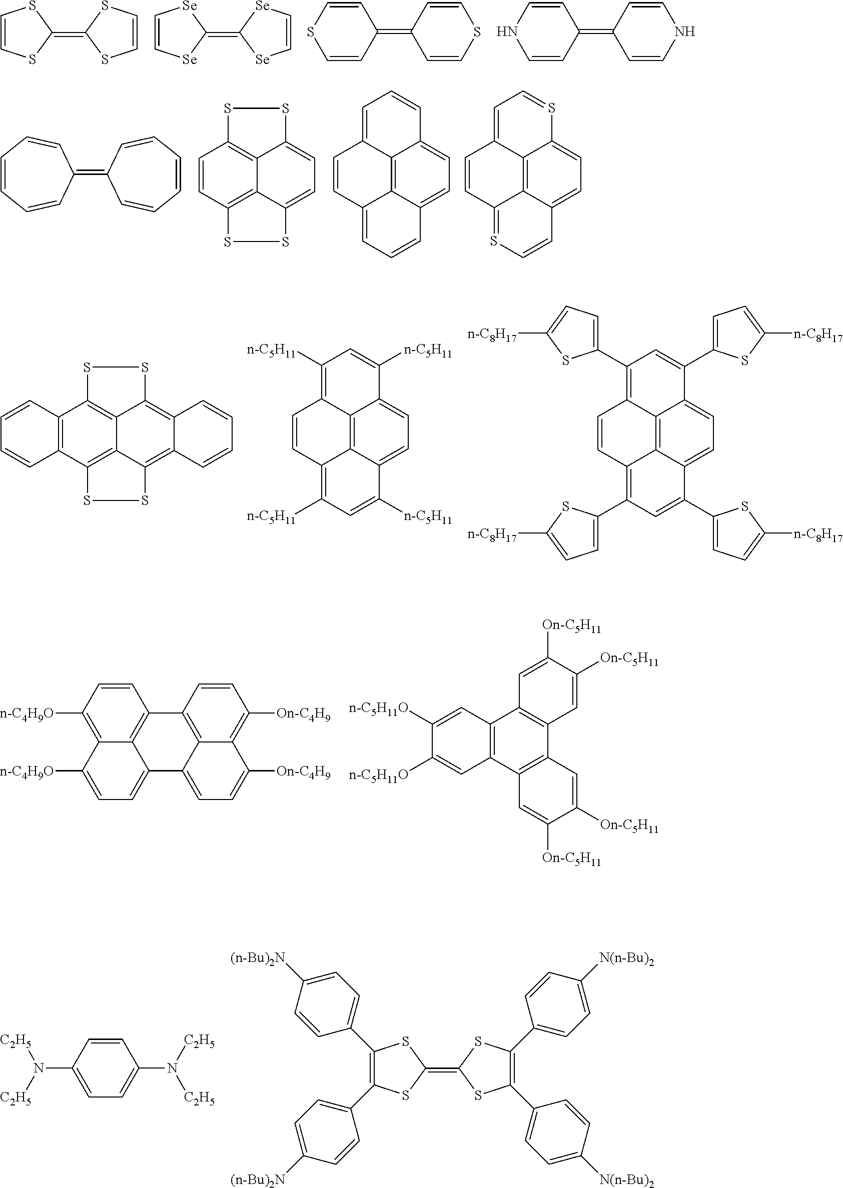

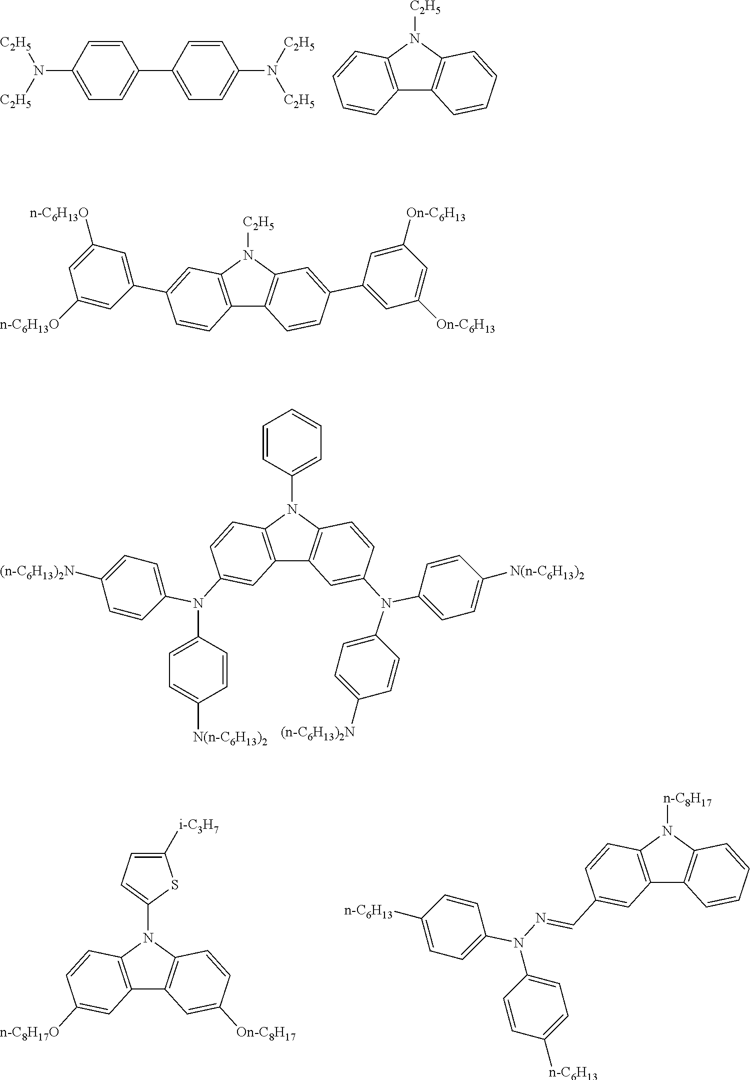

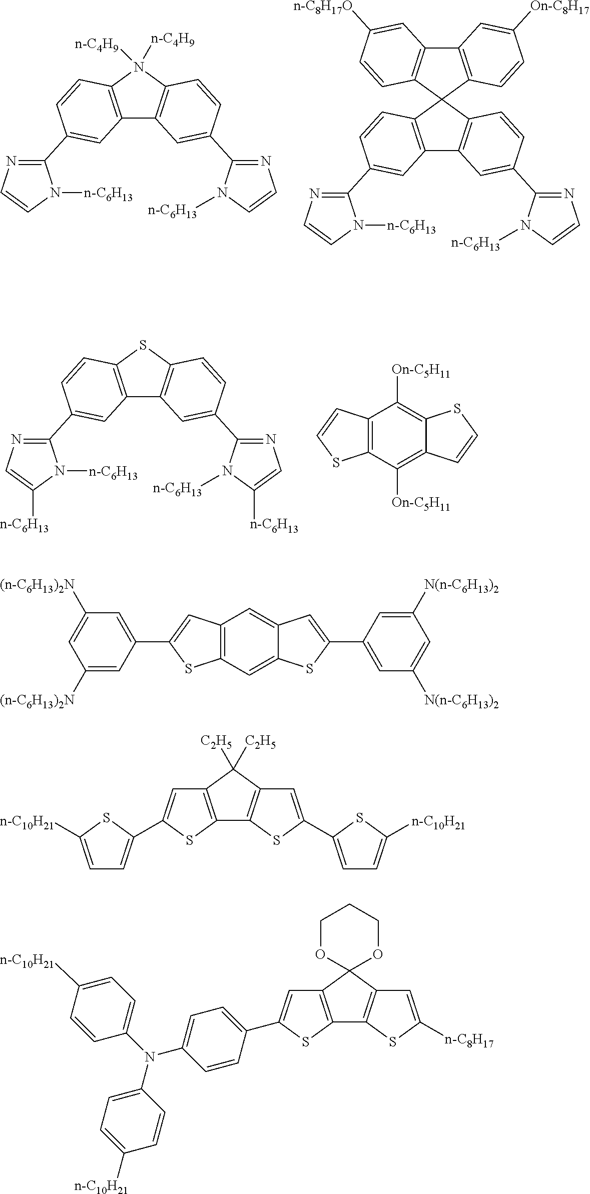

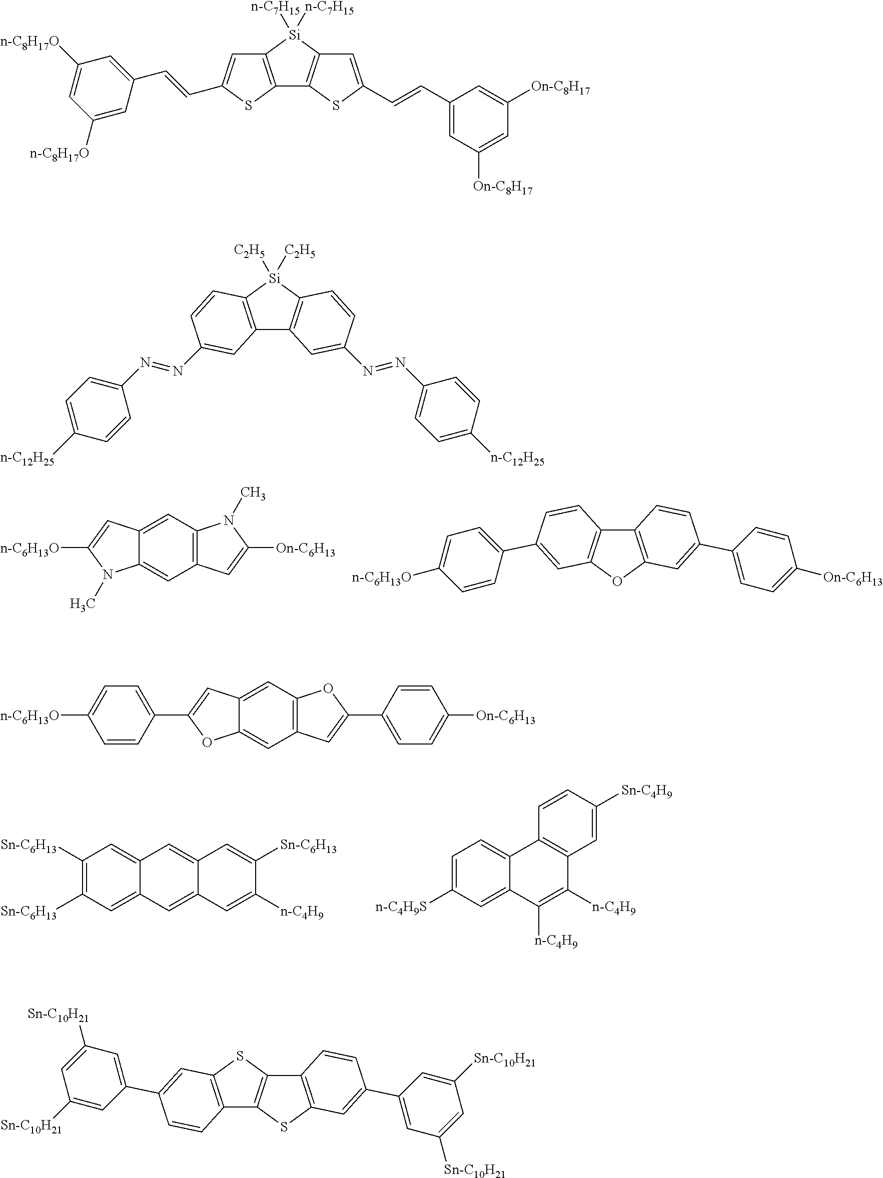

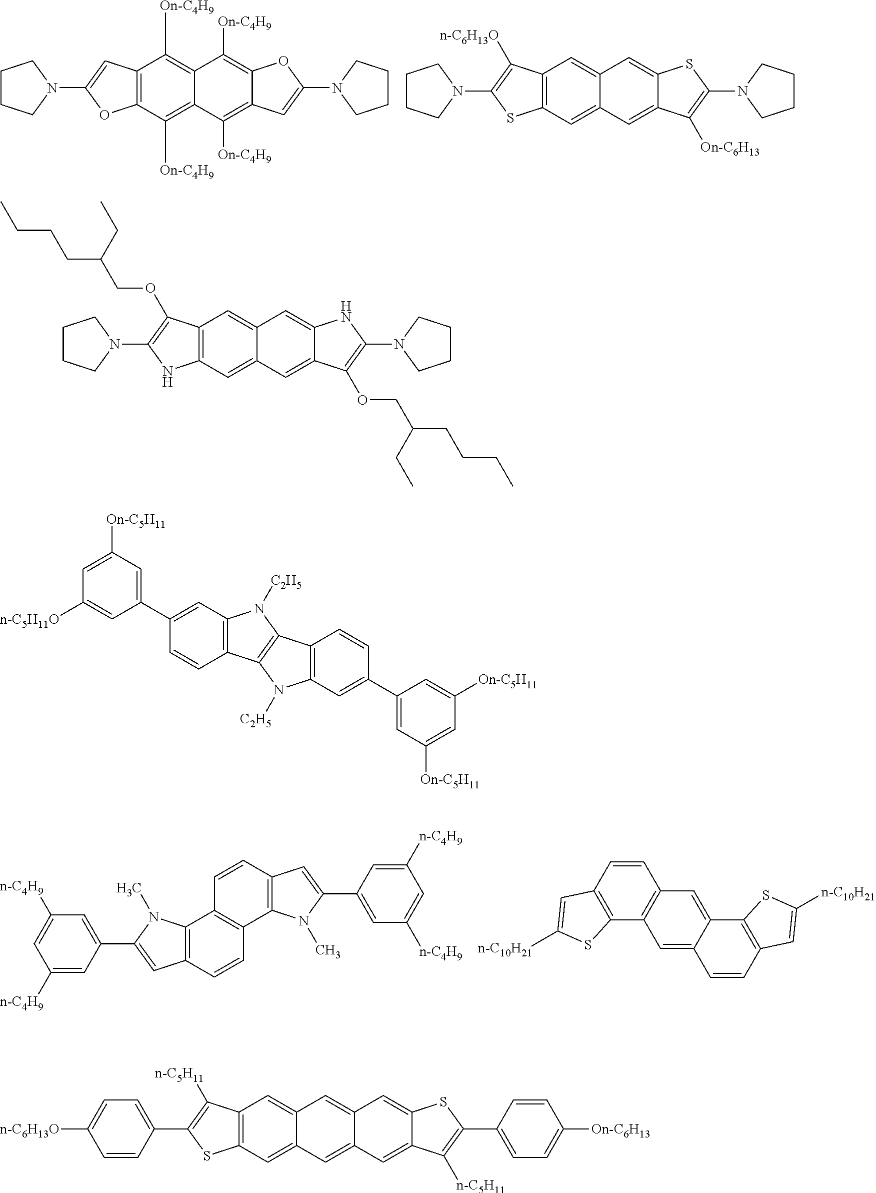

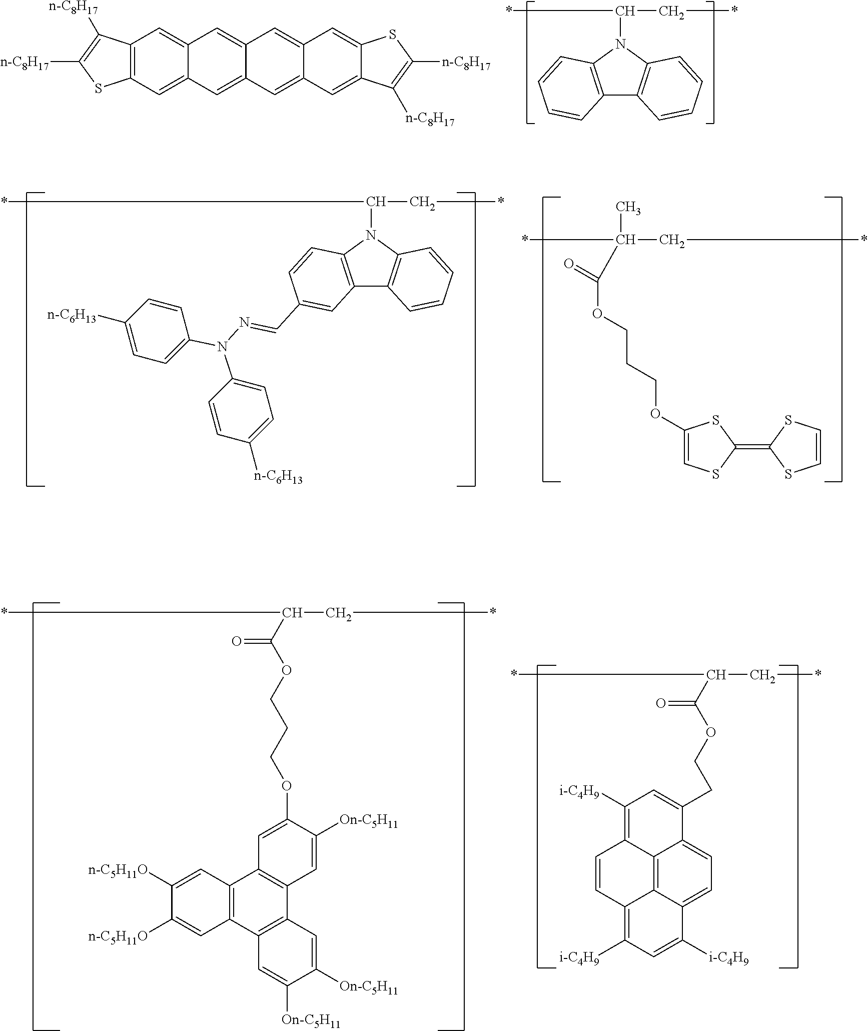

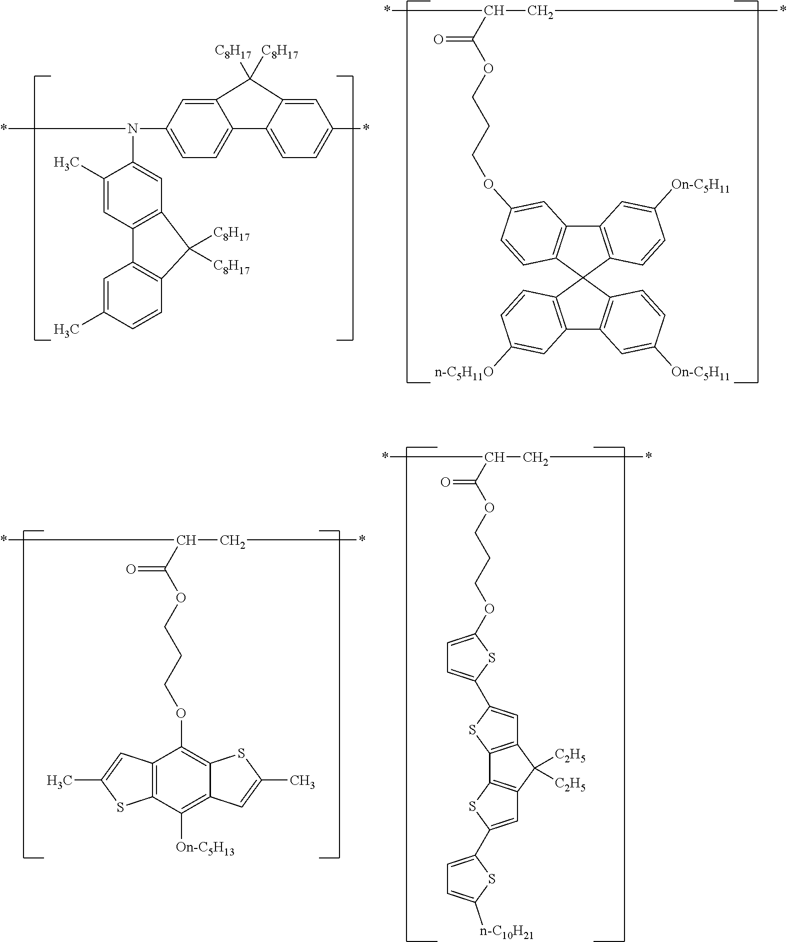

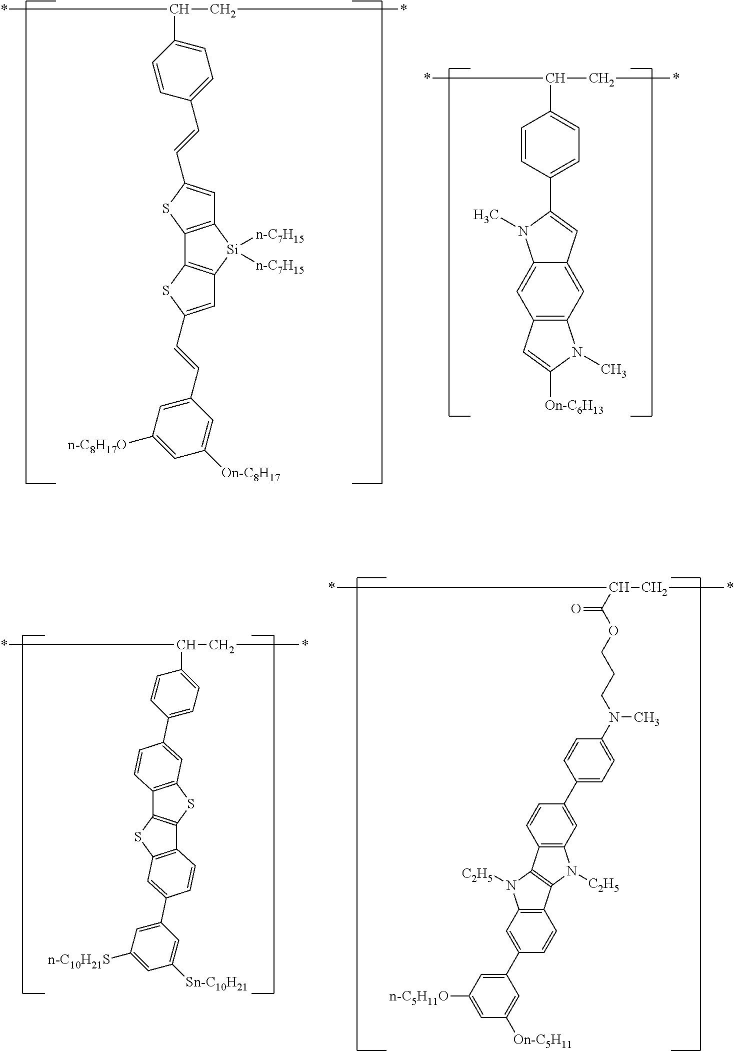

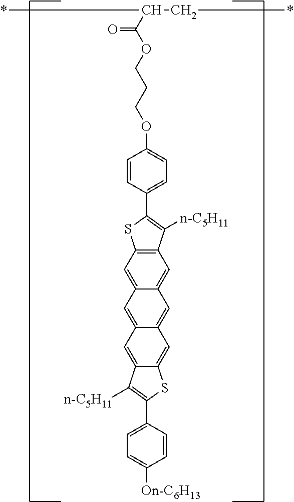

The electron acceptor that constitutes the charge-transfer complex of the invention is an organic compound capable of accepting electrons, and does not contain any metal atom.

The organic electron acceptor is preferably a compound having at least one electron-withdrawing group.

An electron-withdrawing group according to the invention means a substituent whose Hammett substituent constant σp value is greater than 0.

Here, the Hammett substituent constant σp value is explained. Hammett's rule is a rule of thumb advocated by L. P. Hammett in 1935 for quantitatively considering the influence of substituents on the reaction or equilibrium of benzene derivatives, and the appropriateness thereof has been widely recognized. The substituent constants determined in Hammett's rule include σp value and am value, and these values can be found in a large number of general publications, and are described in detail in, for example, J. A. Dean, ed., “Lange's and Handbook of Chemistry”, 12^{th} edition, 1979 (McGraw-Hill), and in “Kagaku no Ryoiki (Realm of Chemistry)”, special issue, No. 122, pp. 96-103, 1979 (Nankodo). Meanwhile, in this invention, substituents are limited or explained based on Hammett's substituent constants σp; however, this does not imply that the substituents are limited only to those substituents having values that are already known in the documents found in the publications described above, and the relevant substituents should include those substituents whose values are not known in the documents but are included in the known ranges when the Hammett substituent constants are measured based on Hammett's rule. Furthermore, compounds that are not benzene derivatives are also included in the organic electron acceptors according to the invention; however, the σp value is used as a measure for indicating the electron effect of a substituent, irrespective of the position of substitution. The σ value is used in such a sense in this invention.

Examples of an electron-withdrawing group having a Hammett substituent constant σ value of 0.60 or more include a cyano group, a nitro group, an alkylsulfonyl group (for example, a methanesulfonyl group), and an arylsulfonyl group (for example, a benzenesulfonyl group).

Examples of an electron-withdrawing group having a Hammett σ value of 0.45 or more include, in addition to the groups described above, an acyl group (for example, an acetyl group), an alkoxycarbonyl group (for example, a dodecyloxycarbonyl group), an aryloxycarbonyl group (for example, a m-chlorophenoxycarbonyl group), an alkylsulfinyl group (for example, a n-propylsulfinyl group), an arylsulfinyl group (for example, a phenylsulfinyl group), a sulfamoyl group (for example, a N-ethylsulfamoyl group or a N,N-dimethylsulfamoyl group), a halogenated alkyl group (for example, a trifluoromethyl group), an ester group, a carbonyl group, and an amide group. Examples of an electron-withdrawing group having a Hammett substituent constant σ value of 0.30 or more include, in addition to the groups described above, an acyloxy group (for example, an acetoxy group), a carbamoyl group (for example, a N-ethylcarbamoyl group or a N,N-dibutylcarbamoyl group), a halogenated alkoxy group (for example, a trifluoromethyloxy group), a halogenated aryloxy group (for example, a pentafluorophenyloxy group), a sulfonyloxy group (for example, a methylsulfonyloxy group), a halogenated alkylthio group (for example, a difluoromethylthio group), an aryl group substituted with two or more electron-withdrawing groups each having a σp value of 0.15 or more (for example, a 2,4-dinitrophenyl group or a pentachlorophenyl group), and a heterocyclic group (for example, a 2-benzoxazolyl group, a 2-benzothiazolyl group, or a 1-phenyl-2-benzimidazolyl group).

Specific examples of an electron-withdrawing group having a σp value of 0.20 or more include halogen atoms, in addition to the groups described above.

The electron-withdrawing group according to the invention is preferably an electron-withdrawing group having a Hammett substituent constant σp value of 0.20 or more. Above all, a cyano group, a nitro group, an alkylsulfonyl group, an arylsulfonyl group, an acyl group, an alkylsulfinyl group, an arylsulfinyl group, a sulfamoyl group, a halogenated alkyl group, an alkoxycarbonyl group, an aryloxycarbonyl group, a halogen atom, and an amide group are preferred; and a cyano group, a nitro group, an alkylsulfonyl group, an arylsulfonyl group, an acyl group, a halogenated alkyl group, an alkoxycarbonyl group, a halogen atom, and an amide group are more preferred.

The organic electron acceptor is preferably a compound represented by the following Formula (2). Meanwhile, when the electron acceptor is a polymeric compound, a polymer which contains a constituent component corresponding to a compound represented by the following Formula (2) as a repeating structure is preferred.

XEWG)ₙₐ Formula (2)

In Formula (2), X represents an organic group having a valence of na. EWG represents an electron-withdrawing group. na represents an integer of 1 or greater.

In Formula (2), the electron-withdrawing group of EWG has the same meaning as the electron-withdrawing group described above, and a preferred range thereof is also the same.

In Formula (2), X is preferably a group having a valence of na which corresponds to a conjugated aliphatic group having 2 or more carbon atoms, an aromatic group, or a group combining these.

The relevant conjugated aliphatic group is an aliphatic group having a conjugated structure composed of unsaturated bonds, and may be any of a linear, branched or cyclic group. The conjugated aliphatic group may also contain a heteroatom. Specific examples of the relevant aliphatic group include aliphatic groups corresponding to ethylene, butadiene, benzoquinone, cyclohexadiene, quinodimethane, cyclohexene, and the like, and aliphatic groups corresponding to benzoquinone, cyclohexadiene, and quinodimethane are preferred.

The relevant aromatic group may be any of an aromatic hydrocarbon ring group or an aromatic heterocyclic group.

The relevant aromatic hydrocarbon ring may be any monocyclic hydrocarbon ring having aromaticity, and an example of the ring that constitutes the base is a benzene ring.

The relevant aromatic hetero ring is not particularly limited as long as it is a monocyclic hetero ring having aromaticity; however, a suitable example is a 5-membered aromatic hetero ring or a 6-membered aromatic hetero ring. Examples of the heteroatom that constitutes the hetero ring include a sulfur atom, a nitrogen atom, and an oxygen atom, and a sulfur atom and a nitrogen atom are preferred. Examples of the 5-membered aromatic hetero ring include a thiophene ring, a furan ring, a pyrrole ring, an imidazole ring, a pyrazole ring, an oxazole ring, an isoxazole ring, a thiazole ring, an isothiazole ring, a triazole ring, and a thiadiazole ring. Examples of the 6-membered aromatic hetero ring include a pyridine ring, a pyrimidine ring, a pyridazine ring, a pyrazine ring, and a triazine ring. Among them, a 5-membered aromatic hetero ring is more preferred, and a thiophene ring, a pyrrole ring, a thiazole ring, and a thiadiazole ring are even more preferred.

These aliphatic groups or aromatic groups may have a substituent other than the electron-withdrawing group EWG described above; however, it is preferable that the aliphatic groups or aromatic groups do not have any substituent.

na represents an integer of 1 or greater, and is preferably an integer of 4 or greater.

The organic electron acceptor used for the invention is preferably a compound having a structure represented by any one of the following Formulae (2A) to (2C):

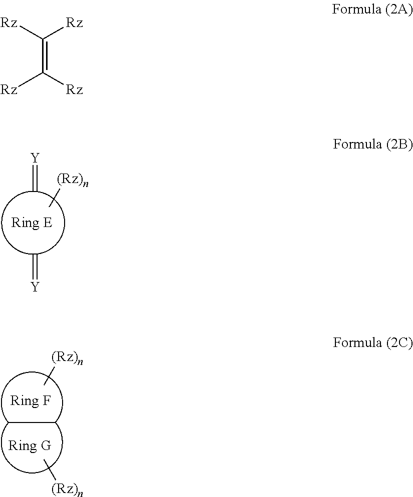

In Formulae (2A) to (2C), Rz represents a substituent. Plural Rz's may be identical or different. Y represents an oxygen atom, or a carbon atom substituted with two electron-withdrawing groups. n represents an integer of 0 or greater. Here, two adjacent Rz's may be bonded to each other to form a ring.

Regarding the substituent for Rz, any substituent other than a group as a pendant incorporated into the polymer is preferably an electron-withdrawing group. Meanwhile, examples of the electron-withdrawing group include the electron-withdrawing groups described above, and a preferred range thereof is also the same.

Regarding Rz, in Formula (2A), Rz is preferably a cyano group; and in Formula (2B), Rz is preferably a halogen atom or a cyano group, and more preferably a halogen atom. In Formula (2C), Rz is preferably a halogen atom, an alkyl group, an alkenyl group, an alkynyl group, an alkoxycarbonyl group, an acyl group, a carbamoyl group, a sulfamoyl group, an alkyl- or arylsulfonyl group, a perfluoroalkyl group, a cyano group, or a nitro group.

The electron-withdrawing group in the case in which Y represents a carbon atom substituted with two electron-withdrawing groups, is preferably a cyano group or an acyl group.

Ring E is preferably a 5-membered or 6-membered ring, and more preferably a 6-membered ring. Furthermore, the ring E is preferably a saturated hydrocarbon ring or an unsaturated hydrocarbon ring, and such a ring may also be fused with an aromatic ring, a non-aromatic hetero ring, or a non-aromatic hydrocarbon ring. Preferred examples of the aromatic ring, non-aromatic hetero ring, or non-aromatic hydrocarbon ring include those mentioned for the above Formulae (1A) and (1B).

Ring E is preferably a 6-membered ring having a quinoid structure.

Ring F and ring G are each preferably a 5-membered or 6-membered ring, and may be any of an aromatic ring, a non-aromatic hetero ring, or a non-aromatic hydrocarbon ring. Preferred examples of the aromatic ring, non-aromatic hetero ring, or non-aromatic hydrocarbon ring include the rings mentioned for the above Formulae (1A) and (1B). In addition, the aromatic ring, non-aromatic hetero ring, or non-aromatic hydrocarbon ring may be further fused.

Ring F or ring G is preferably a ring selected from a benzene ring, a naphthalene ring, a pyridine ring, a thiophene ring, a thiadiazole ring, an imidazolidinone ring, a thiazole ring, a 2H-imidazole ring, a pyrazolone ring, a pyrrolidinedione ring, and a cyclopentadienone ring.

Specific examples of the organic electron acceptor used for the invention are shown below; however, the invention is not intended to be limited to these. Meanwhile, in the following specific examples, the symbol * represents the linking site of a repeating structure.

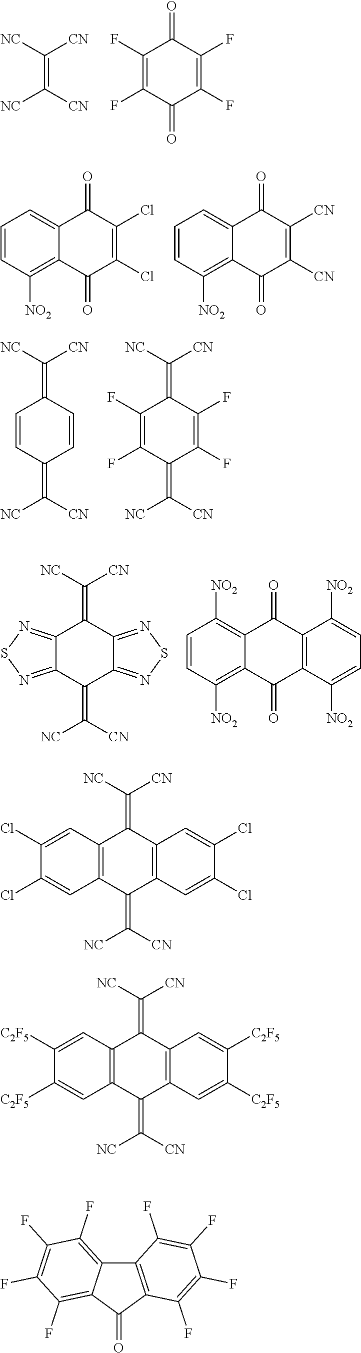

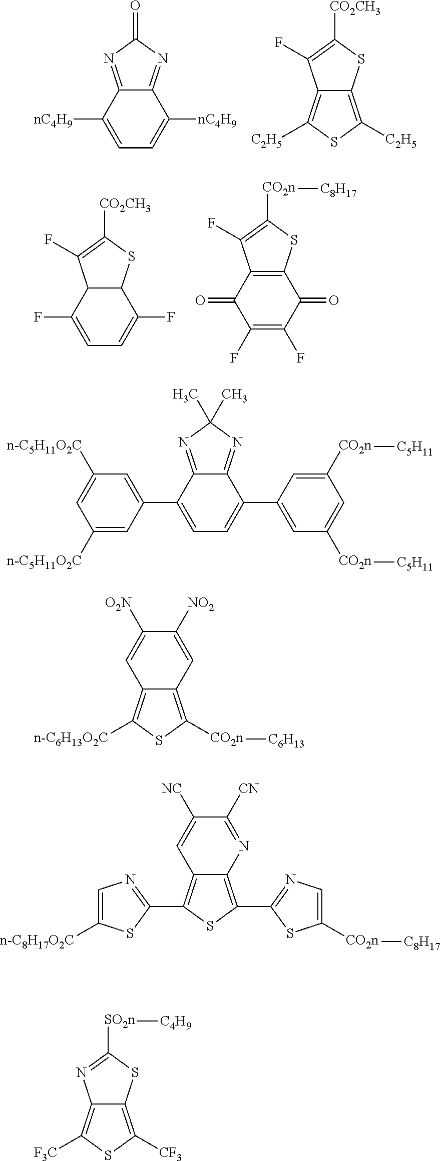

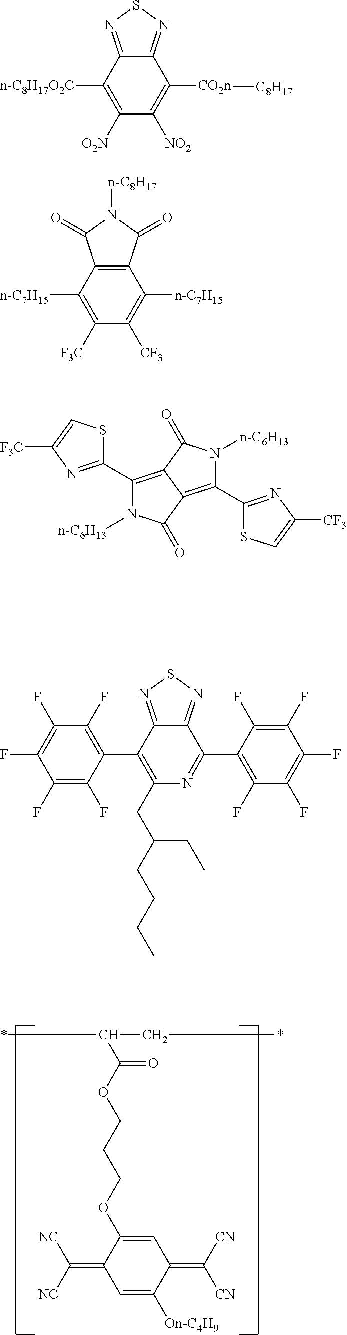

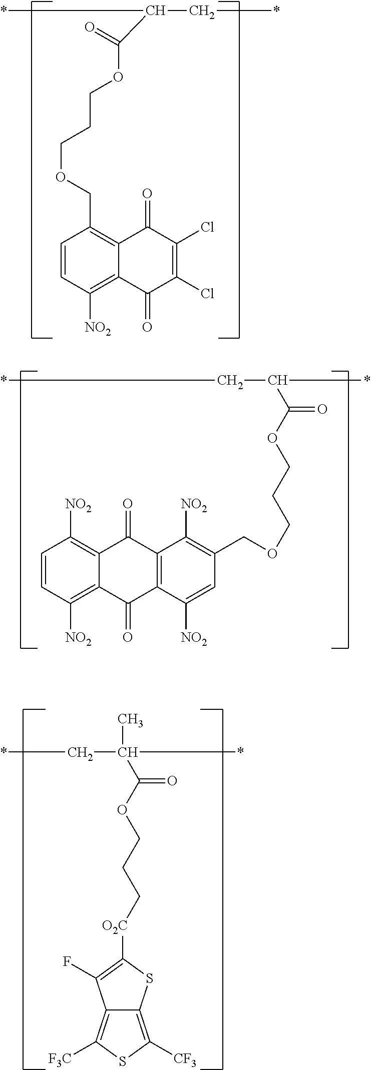

Regarding the charge-transfer complex used for the invention, a commercially available product can be used, or the charge-transfer complex may also be appropriately synthesized in the same manner as in the Examples described below.

(Arylamine Compound)

The arylamine compound used for the invention has a particular optical band gap, and therefore, the arylamine compound can enhance the performance of the thermoelectric conversion element when used together with an electroconductive nanomaterial as explained above.

The percentage content of the arylamine compound in the thermoelectric conversion material is preferably 5 parts by mass to 500 parts by mass, and more preferably 20 parts by mass to 200 parts by mass, relative to 100 parts by mass of the electroconductive nanomaterial, from the viewpoint of the thermoelectric conversion performance.

In the thermoelectric conversion material of the invention, an arylamine compound may be used singly, or two or more kinds thereof may be used in combination.

The arylamine compound used for the invention is preferably a one-electron oxidant of an arylamine compound represented by the following Formula (4A), or a two-electron oxidant of an arylamine compound represented by the following Formula (4B).

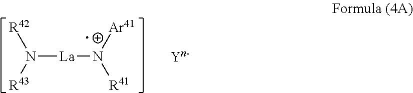

In Formula (4A), La represents an arylene group, a heteroarylene group, or a group combining these. Ar⁴¹ represents an aromatic hydrocarbon ring group or an aromatic heterocyclic group. R⁴¹ to R⁴³ each independently represent an aromatic hydrocarbon ring group, an aromatic heterocyclic group, an alkyl group, an aryl group, or a cycloalkyl group. Y represents an arbitrary counter-anion. n of n− represents an integer of 1 or greater.

Here, when n is 2 or greater, the compound has a cationic substituent or partial structure (preferably a radical cation of another nitrogen atom) on any one of Ar⁴¹ and R⁴¹ to R⁴³; however, it is not necessary for the compound to have the one-electron oxidized nitrogen atom at a position that is π-conjugated with the one-electron oxidized nitrogen atom. It is necessary that the conjugation is divided by an alkylene group or the like. If the substituent or partial structure exists at a conjugated position, the compound adopts a quinoid structure.

The oxidation state of a two-electron oxidant or higher oxidant is unstable, and n is preferably 2.

The arylene group for La is preferably a phenylene group. The hetero ring in the heteroarylene group for La is preferably a 5-membered or 6-membered ring, and may be fused with a benzene ring or a hetero ring. Examples include a thiophene ring, a thiazole ring, and a pyridine ring, and specific examples are thiophene-2,5-diyl and benzo[1,2-b:4,5-b′]dithiophene-2,6-diyl. Also, an example of a group combining these is a biphenylene group.

The one-electron oxidant of an arylamine compound represented by Formula (4A) is preferably a one-electron oxidant represented by the following Formula (4A-1).

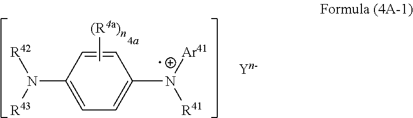

In Formula (4A-1), Ar⁴¹, R⁴¹ to R⁴³, Y, and n− have the same meanings as Ar⁴¹, R⁴¹ to R⁴³, Y, and n− for the above Formula (4A), respectively, and preferred ranges thereof are also the same; R^{4a} represents a substituent; and n₄ₐ represents an integer from 0 to 4.

The substituent for R^{4a} is preferably an alkyl group or a halogen atom.

On the other hand, a two-electron oxidant is a compound having a quinoid structure (quinonediimine structure).

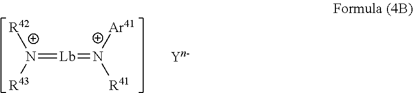

In Formula (4B), Lb represents a group having a structure of a quinoid type aromatic hydrocarbon ring, a group having a structure of a quinoid type aromatic hetero ring, or a group combining these. Ar⁴¹, R⁴¹ to R⁴³, Y, and n− have the same meanings as Ar⁴¹, R⁴¹ to R⁴³, Y, and n− for the above Formula (4A), respectively, and preferred ranges thereof are also the same. n of n− represents an integer of 2 or greater.

Here, when n is 3 or greater, the compound may have a cationic substituent or partial structure on any one of Ar⁴¹ and R⁴¹ to R⁴³; however, the oxidation state of a two-electron oxidant or higher oxidant is unstable, and n is preferably 2.

The group having a structure of a quinoid type aromatic hydrocarbon ring for Lb is preferably a group having a structure of a quinoid of a benzene ring. The aromatic hetero ring in the group having a structure of a quinoid of an aromatic hetero ring for Lb is preferably a 5-membered or 6-membered ring, and the aromatic hetero ring may be fused with a benzene ring or a hetero ring. Examples include a thiophene ring, a thiazole ring, and a pyridine ring, and specific examples include thiophenyl-2,5-diidene and benzo[1,2-b:4,5-b′]dithiophenyl-2,6-diidene. Furthermore, an example of a group combining these is a group having a structure of a quinoid of a biphenylene group.

The two-electron oxidant of an arylamine compound represented by Formula (4B) is preferably a two-electron oxidant represented by the following Formula (4B-1).

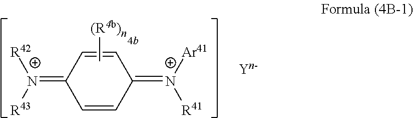

In Formula (4B-1), Ar⁴¹, R⁴¹ to R⁴³, Y, and n− have the same meanings as Ar⁴¹, R⁴¹ to R⁴³, Y, and n− for the above Formula (4B), respectively, and preferred ranges thereof are also the same; R^{4b} represents a substituent; and n_{4b} represents an integer from 0 to 4.

The substituent for R^{4b} is preferably an alkyl group or a halogen atom.

The arylamine compound used for the invention is preferably an arylamine compound represented by the following Formula (5), or a one-electron or two-electron oxidant of the compound. The one-electron or two-electron oxidant of the arylamine compound represented by Formula (5) may have an arbitrary counter-anion.

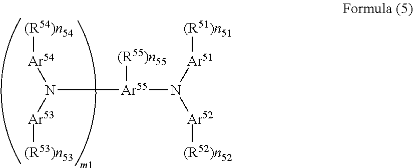

In Formula (5), Ar⁵¹ to Ar⁵⁵ each independently represent an aromatic hydrocarbon ring, an aromatic hetero ring, a single bond, or an alkylene group. However, at least one of Ar⁵¹ and Ar⁵², and at least one of Ar⁵³ and Ar⁵⁴ are aromatic hydrocarbon rings. R⁵¹ to R⁵⁵ each independently represent a substituent. n₅₁ to n₅₅ each independently represent an integer from 0 to 3. m1 represents 0 or 1.

Examples of the aromatic hydrocarbon ring for Ar⁵¹ to Ar⁵⁵ include a benzene ring and a naphthalene ring, and a benzene ring is preferred.

Examples of the aromatic hetero ring for Ar⁵¹ to Ar⁵⁵ include a pyrrole ring, a thiophene ring, a furan ring, an imidazole ring, a pyrazole ring, an oxazole ring, an isoxazole ring, a thiazole ring, an isothiazole ring, a silole ring, a selenophene ring, a tellurophene ring, a benzoquinone ring, a cyclopentadiene ring, a pyridine ring, a pyridon-2-one ring, a pyrimidine ring, a pyridazine ring, a pyrazine ring, and a triazine ring, and a thiophene ring, a furan ring, and a pyridine ring are preferred.

Examples of the alkylene group for Ar⁵¹ to Ar⁵⁵ include an alkylene group having 2 to 14 carbon atoms, and an alkylene group having 2 to 8 carbon atoms is preferred.

Examples of the substituent for R⁵¹ to R⁵⁵ include an alkyl group, an alkenyl group, an alkynyl group, an amino group, a dialkylamino group, a diarylamino group, a N-alkyl-N-arylamino group, an alkoxy group, an aryloxy group, an alkylthio group, an arylthio group, and a halogen atom. These groups may be further substituted. For example, the aryl moiety of the diarylamino group may be further substituted with a dialkylamino group or a diarylamino group.

Furthermore, a hydrogen atom of an alkyl moiety of such a group may be substituted by a halogen atom. The substituent for R⁵¹ to R⁵⁵ is preferably a dialkylamino group, a diarylamino group, or an alkoxy group, and more preferably an alkylamino group.

The one-electron oxidant of a compound represented by Formula (5) is a product in which a nitrogen atom substituted with at least one aromatic ring contained in the above Formula (5) (>N−) has been converted to a radical cation (>N·⁺−).

Meanwhile, in the present specification, a one-electron oxidant means the oxidation state of one nitrogen atom, and the one-electron oxidant also includes a compound in which another nitrogen atom existing at a position that cannot adopt a quinoid structure is one-electron oxidized, and thus there are two or more radical cationic nitrogen atoms in total.

Specific examples of the arylamine compound used for the invention are shown below; however, the invention is not intended to be limited to these. Also, these compounds may have arbitrary counter-anions.

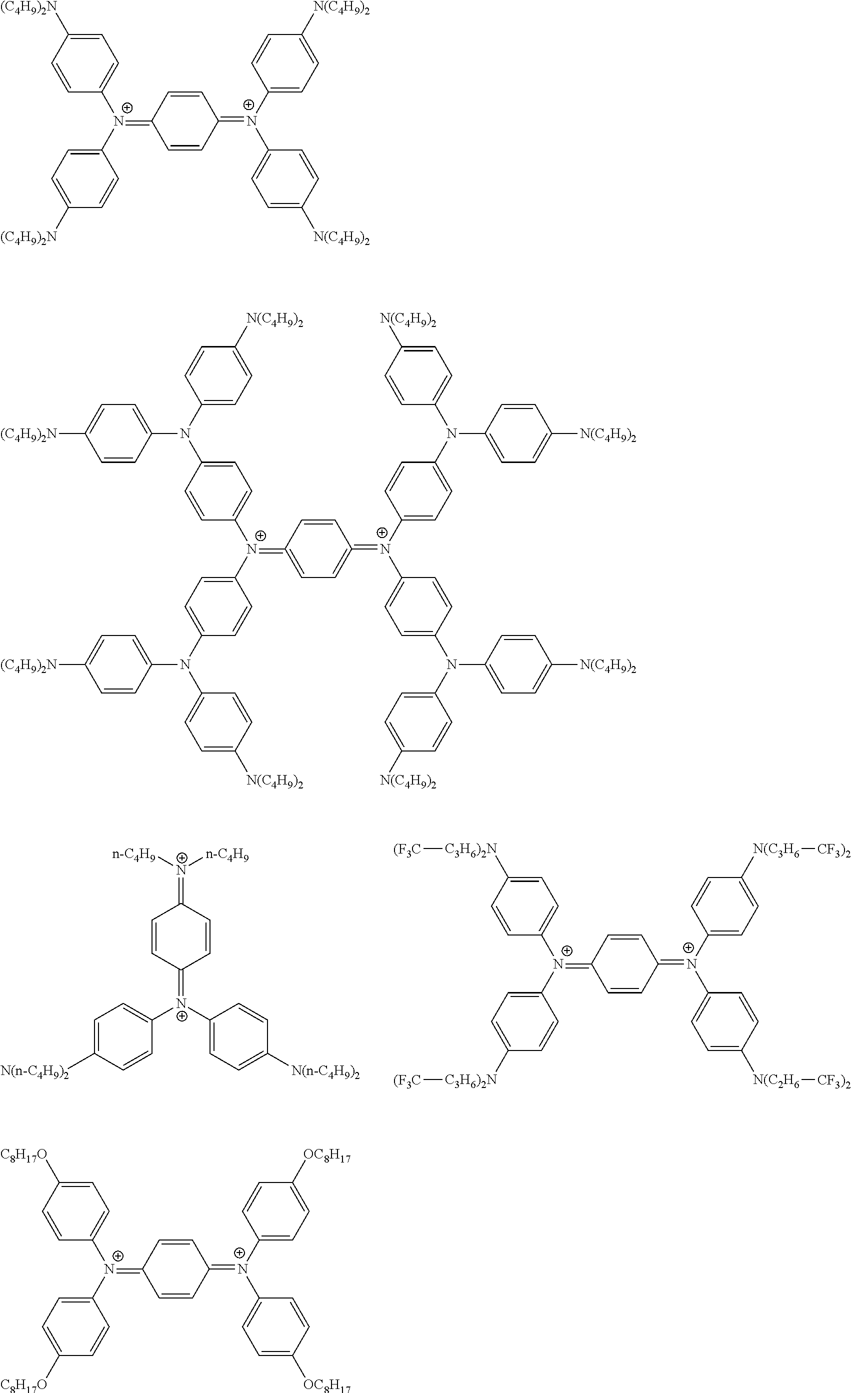

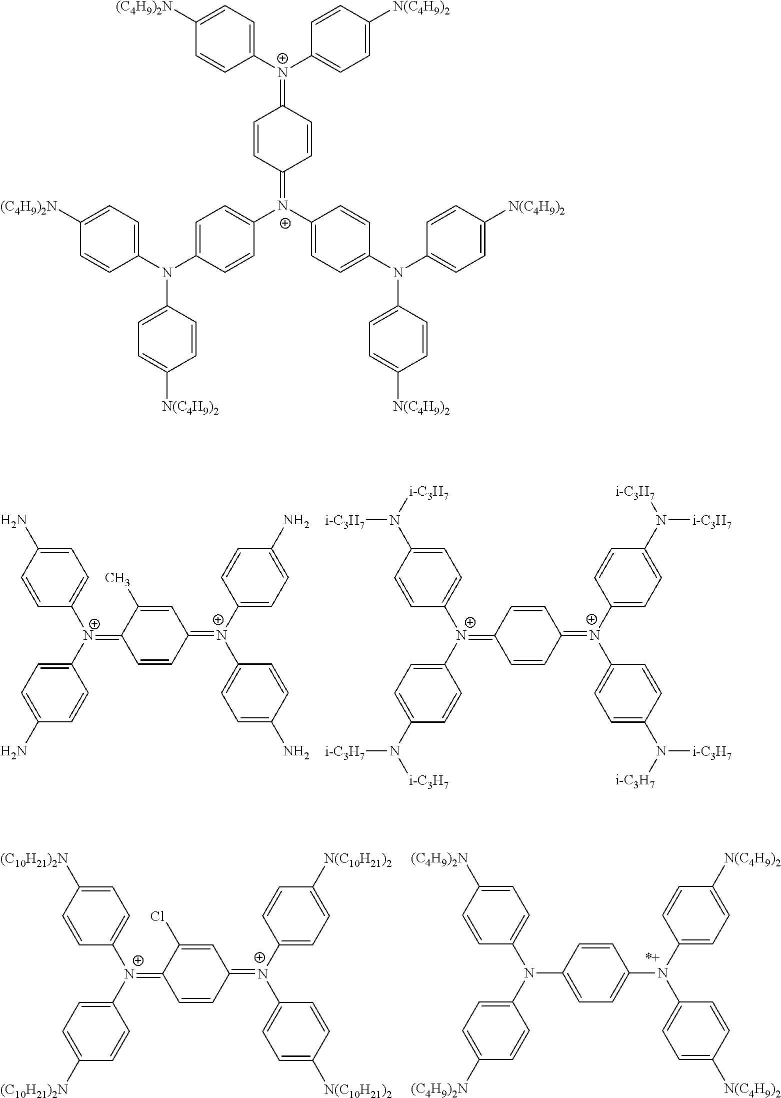

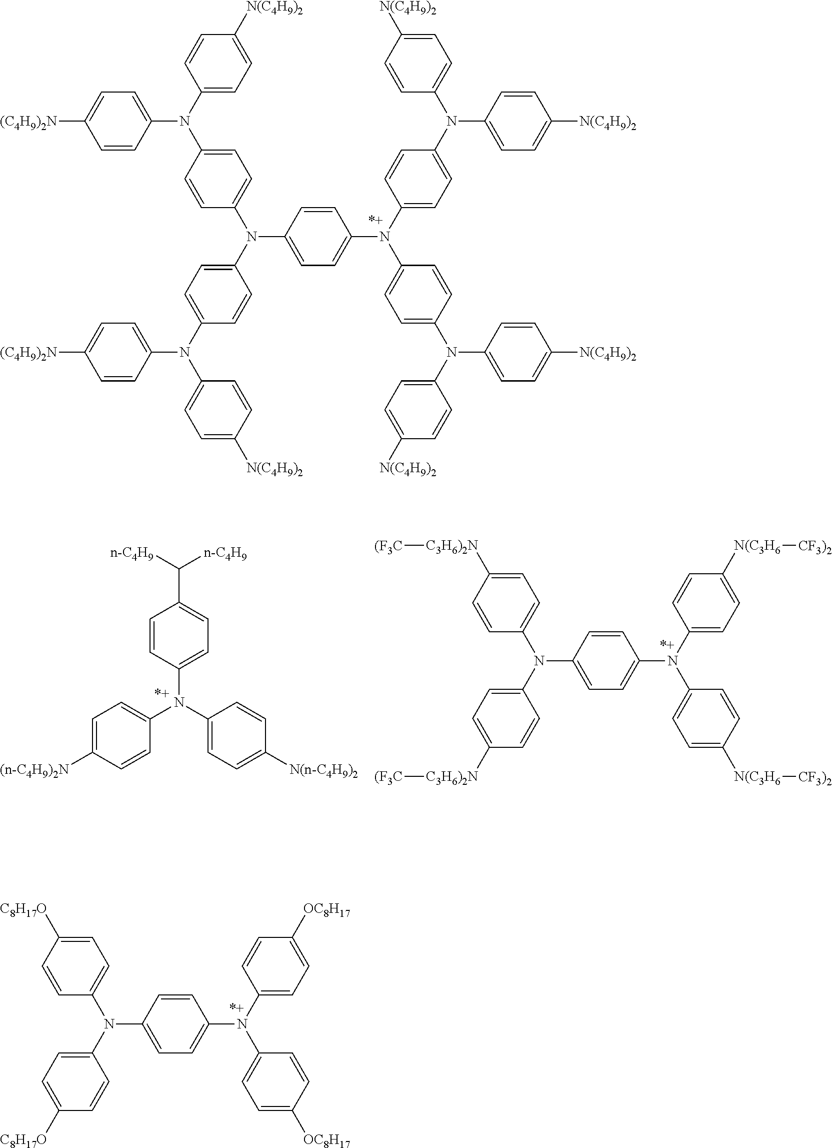

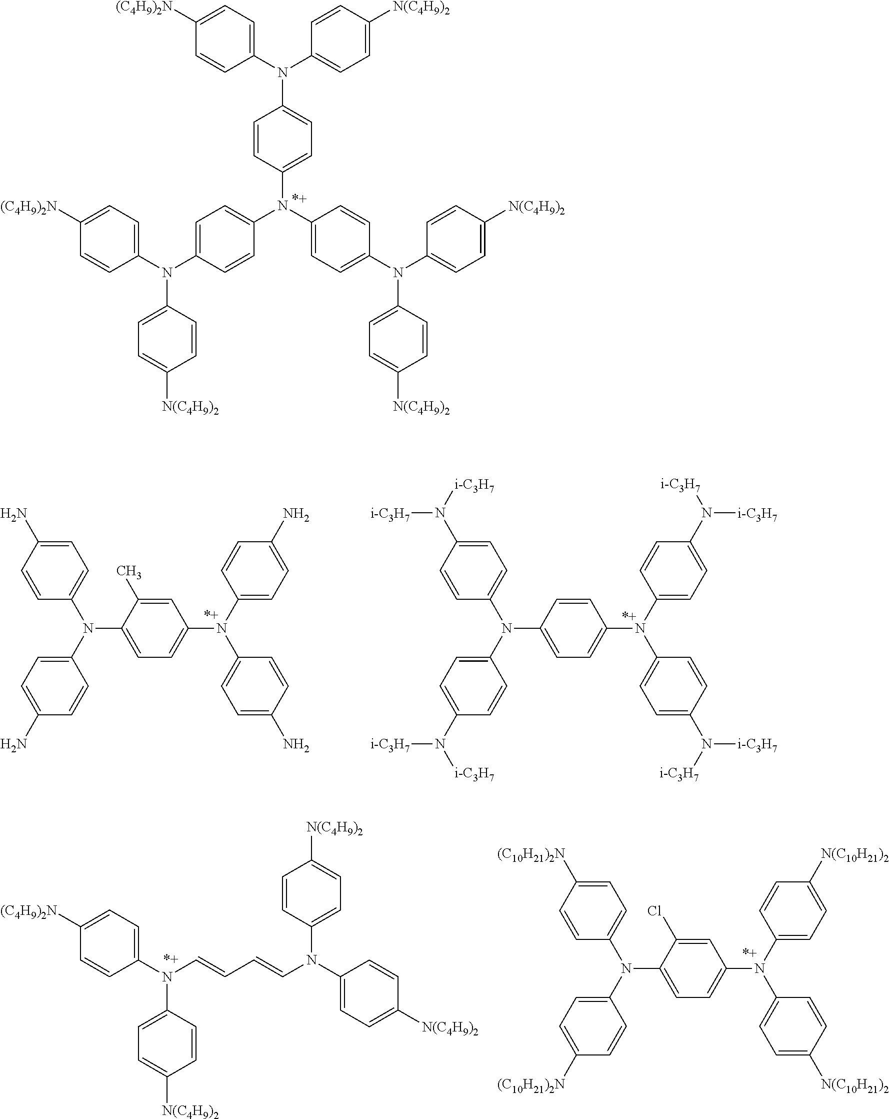

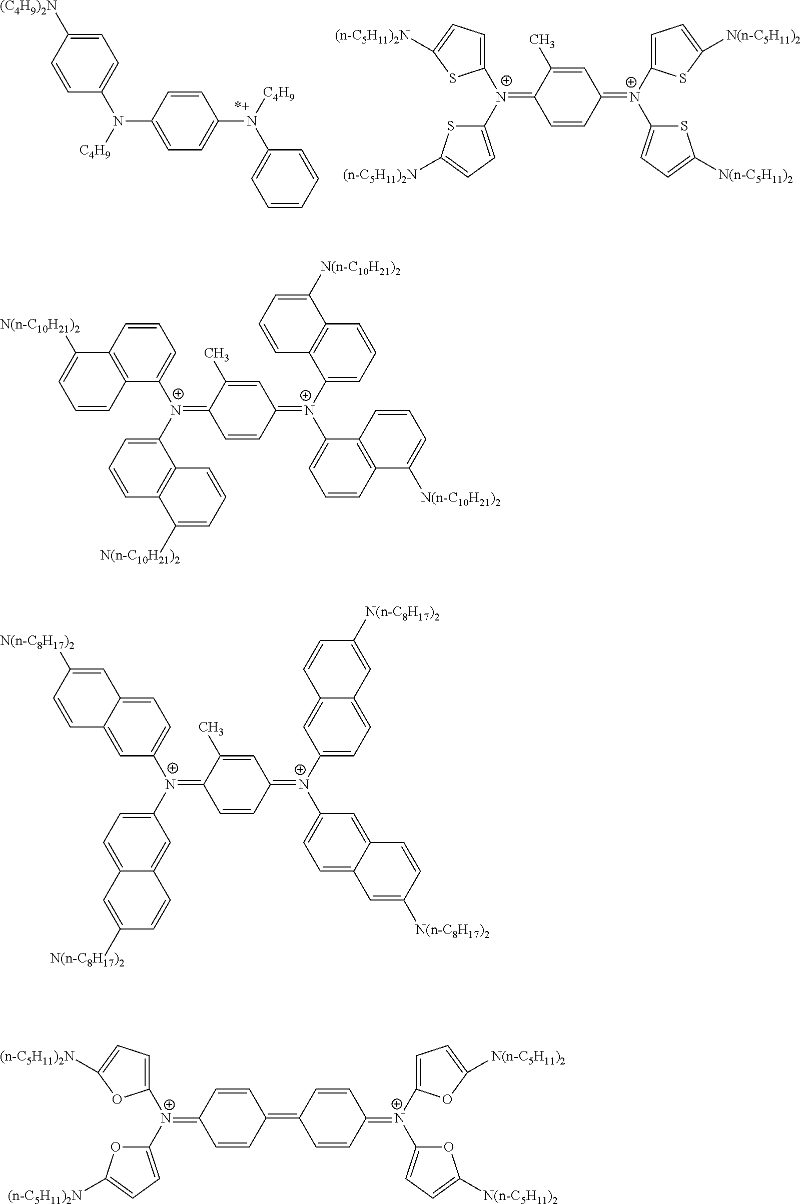

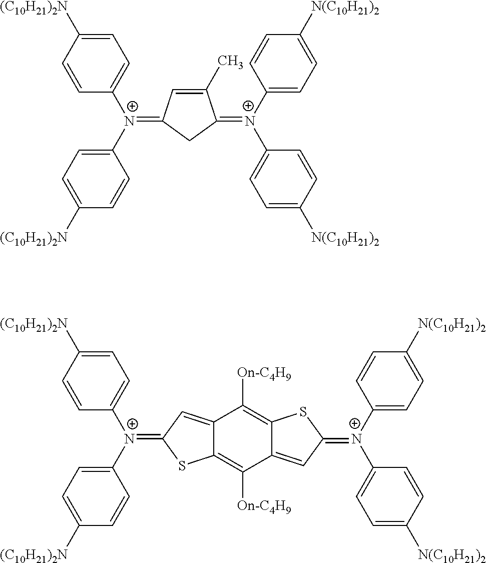

Regarding the arylamine compound used for the invention, a commercially available product can be used, or the arylamine compound may be chemically synthesized.

(Electroconductive Polymer)

The electroconductive polymer that is used as the material for a thermal excitation source is not particularly limited as long as the electroconductive polymer satisfies the conditions described above, and any conventionally known electroconductive polymer can be used. Specifically, polyacetylene, polythiophene, and the like can be used.

(Polythiophene)

The polythiophene that is used as the material for a thermal excitation source is not particularly limited as long as the compound satisfies the conditions described above.

A polythiophene that can be used in the invention has a structure in which a constituent component derived from at least one compound selected from the group of thiophene-based compounds is repeated, and it is preferable that the polythiophene is doped with an acid. There are no particular limitations on the substituent to be introduced into the polythiophene; however, in consideration of the compatibility with other components, the kind of the dispersing medium that can be used, and the like, it is preferable to appropriately select and introduce into the polythiophene a substituent that can increase the dispersibility of the conjugated polymer in a dispersing medium.

As an example of the substituent, in the case of using an organic solvent as the dispersing medium, a linear, branched or cyclic alkyl group, an alkenyl group, an alkynyl group, an alkoxy group, a thioalkyl group, an alkoxyalkyleneoxy group, an alkoxyalkyleneoxyalkyl group, a crown ether group, an aryl group, and the like can be preferably used. These groups may further have substituents. Also, there are no particular limitations on the number of carbon atoms of the substituent; however, the number of carbon atoms is preferably 1 to 12, and more preferably 4 to 12. Particularly, an alkyl group having a long chain with 6 to 12 carbon atoms, an alkoxy group, a thioalkyl group, an alkoxyalkyleneoxy group, and an alkoxyalkyleneoxyalkyl group are preferred.

Furthermore, regarding the doping material that is used for the polythiophene, organic acids and inorganic acids such as sulfonic acid, carboxylic acid, and phosphoric acid can be used.

<Non-Conjugated Polymer>

The composition of the first embodiment and the composition of the second embodiment of the invention may respectively include a non-conjugated polymer.

The term non-conjugated polymer refers to a polymer compound which does not have a conjugated molecular structure, and specifically refers to a polymer compound in which respective repeating units are bonded by non-conjugated bonds (for example, an ordinary single bond) in the main chain direction of the polymer.

Furthermore, the non-conjugated polymer may be a homopolymer, or may be a copolymer.

When the composition includes a non-conjugated polymer, the thermoelectric characteristics are further enhanced. This is speculated to be because, since a non-conjugated polymer affects the dispersibility of an electroconductive nanomaterial, the electroconductive nanomaterial is in a preferable dispersed form, and consequently, thermal conductivity or electrical conductivity is enhanced.

According to the invention, the kind of the non-conjugated polymer is not particularly limited, and any conventionally known non-conjugated polymer can be used. Specifically, a polymer compound obtained by polymerizing a compound selected from the group consisting of a vinyl compound, a (meth)acrylate compound, a carbonate compound, an ester compound, an amide compound, an imide compound, and a siloxane compound can be suitably used.

Meanwhile, according to the invention, the term “(meth)acrylate” refers to any one or both of acrylate and methacrylate.

Specific examples of the vinyl compound include styrene, vinylpyrrolidone, vinylcarbazole, vinylpyridine, vinylnaphthalene, vinylphenol, vinyl acetate, styrenesulfonic acid, vinyl alcohol, vinylarylamines (for example, vinyltriphenylamine), and vinyltrialkylamines (for example, vinyltributylamine).

Specific examples of the (meth)acrylate compound include alkyl group-containing hydrophobic acrylates such as methyl acrylate, ethyl acrylate, propyl acrylate, and butyl acrylate; hydroxyl group-containing acrylates such as 2-hydroxyethyl acrylate, 1-hydroxyethyl acrylate, 2-hydroxypropyl acrylate, 3-hydroxypropyl acrylate, 1-hydroxypropyl acrylate, 4-hydroxybutyl acrylate, 3-hydroxybutyl acrylate, 2-hydroxybutyl acrylate, and 1-hydroxybutyl acrylate; and methacrylate-based monomers obtained by changing the acryloyl groups of the aforementioned monomers to methacryloyl groups.

Specific examples of a polymer obtained by polymerizing a carbonate compound include a general-purpose polycarbonate formed from bisphenol A and phosgene, IUPIZETA (manufactured by Mitsubishi Gas Chemical Company, Inc.), and PANLITE (manufactured by TEIJIN LIMITED).

Specific examples of the ester compound include lactic acid. Also, specific examples of a polymer obtained by polymerizing an ester compound include VYLON (manufactured by Toyobo Co., Ltd.).

Specific examples of a polymer obtained by polymerizing an amide compound include PA-100 (manufactured by T&K Toka Corporation).

Specific examples of a polymer obtained by polymerizing an imide compound include SOLPIT 6,6-PI (Solpit Industries, Ltd.).

Specific examples of the siloxane compound include diphenylsiloxane and phenylmethylsiloxane.

The non-conjugated polymer may be a homopolymer, or may be a copolymer.

Among these, it is more preferable to use a polymer compound formed by polymerizing a vinyl compound, as the non-conjugated polymer.

According to the invention, it is preferable that the non-conjugated polymer is hydrophobic, and it is more preferable that the non-conjugated polymer does not have any hydrophilic group such as sulfonic acid or a hydroxyl group in the molecule.

Furthermore, a non-conjugated polymer having a solubility parameter (SP value) of 11 or less is preferred.

In a case in which a non-conjugated polymer is used in combination with an electroconductive polymer, the content of the non-conjugated polymer is preferably 10 parts by mass to 1500 parts by mass, more preferably 30 parts by mass to 1200 parts by mass, and particularly preferably 80 parts by mass to 1,000 parts by mass, relative to 100 parts by mass of the electroconductive polymer.

<Dopant>

It is preferable that the composition of the invention includes a dopant, for the reason that the carrier concentration increases, and the electrical conductivity is increased.

Examples of the dopant include an onium salt compound (particularly, a compound which generates an acid when irradiated with active energy radiation or applied with heat), an oxidizing agent, an acidic compound, an electron acceptor compound, and a transition metal compound, and these may be used singly or in combination of two or more kinds thereof.

Regarding such a dopant, for example, those described in paragraphs “0043” to “0083” of JP2013-089798A can be appropriately employed.

According to the invention, when the composition includes an arbitrary dopant, the content thereof is preferably 0.1 wt % to 20 wt %, and particularly preferably 1 wt % to 10 wt %, of the material for carrier transport.

<Thermal Excitation Assisting Agent>

It is preferable that the composition of the invention includes a thermal excitation assisting agent, for the reason that more satisfactory thermoelectric characteristics are obtained.

Regarding the thermal excitation assisting agent, for example, those described in paragraphs “0079” to “0089” of JP2013-098299A can be appropriately employed.

According to the invention, such a thermal excitation assisting agent may be used singly, or two or more kinds thereof may be used in combination.

Furthermore, the content of an arbitrary thermal excitation assisting agent is preferably 0% by mass to 35% by mass, more preferably 3% by mass to 25% by mass, and particularly preferably 5% by mass to 20% by mass, relative to the total solid content of the composition.

Similarly, the content of an arbitrary thermal excitation assisting agent is preferably 0.1 wt % to 50 wt %, and more preferably 1 wt % to 50 wt %, of the material having a band gap of 1.5 eV or less.

<Solvent>

It is preferable that the composition of the invention includes a solvent.

The solvent may be any solvent capable of satisfactorily dispersing or dissolving various components, and water, an organic solvent, and a mixed solvent thereof can be used. It is preferable to use an organic solvent.

Examples of the organic solvent include an alcohol, a halogen-based solvent such as chloroform; an aprotic polar solvent such as DMF, NMP, or DMSO; an aromatic solvent such as chlorobenzene, dichlorobenzene, benzene, toluene, xylene, mesitylene, tetralin, tetramethylbenzene, or pyridine; a ketone-based solvent such as cyclohexanone, acetone, or methyl ethyl ketone; and an ether-based solvent such as diethyl ether, THF, t-butyl methyl ether, dimethoxyethane, or diglyme.

Furthermore, it is preferable that the solvent is degassed in advance. It is preferable to have the dissolved oxygen concentration in the solvent adjusted to 10 ppm or less. Examples of the method for degassing include a method of applying ultrasonic waves under reduced pressure, and a method of bubbling with an inert gas such as argon.

Similarly, it is preferable that the solvent is dehydrated in advance. It is preferable to adjust the amount of moisture in the solvent to 1,000 ppm or less, and more preferably to 100 ppm or less. Regarding the method for dehydration, known methods such as a method of using a molecular sieve, and distillation can be used.

According to the invention, in the case of using an arbitrary solvent, the content thereof is preferably 0.01% by mass to 20% by mass, more preferably 0.01% by mass to 10% by mass, and even more preferably 0.01% by mass to 5% by mass, relative to the total mass of the composition.

<Other Components>

The composition of the invention may appropriately include an oxidation inhibitor, a light-fast stabilizer, a heat-resistant stabilizer, a plasticizer and the like, in addition to the various components described above.

The content of these components is preferably 5% by mass or less, and more preferably 0% by mass to 2% by mass, relative to the total solid content of the composition.

Examples of the oxidation inhibitor include IRGANOX 1010 (manufactured by Ciba-Geigy Japan Limited), SUMILIZER GA-80 (manufactured by Sumitomo Chemical Co., Ltd.), SUMILIZER GS (manufactured by Sumitomo Chemical Co., Ltd.), and SUMILIZER GM (manufactured by Sumitomo Chemical Co., Ltd.).

Examples of the light-fast stabilizer include TINUVIN 234 (manufactured by BASF), CHIMASSORB 81 (manufactured by BASF), and CYASORB UV-3853 (manufactured by Sun Chemical Company LTD.).

Examples of the heat-resistant stabilizer include IRGANOX 1726 (manufactured by BASF).

Examples of the plasticizer include ADEKACIZER RS (manufactured by Adeka Corp.).

<Percent Water Content>

Regarding the composition of the invention, due to the reason that the electrical conductivity is increased, the thermoelectric conversion layer thus formed has excellent physical strength, and the stability against an external physical impact or friction from the outside is also enhanced, the percent water content in the composition is preferably from 0.01% by mass to 15% by mass, more preferably from 0.01% by mass to 10% by mass, and even more preferably from 0.1% by mass to 5% by mass.

Here, the percent water content can be evaluated by measuring the equilibrium percent water content under constant temperature and constant humidity conditions. The equilibrium percent water content can be determined by leaving a sample to stand for 6 hours at 25° C. and 60% RH to reach an equilibrium, subsequently measuring the amount of moisture by the Karl-Fischer method using a moisture measuring device and a sample drying apparatus (CA-03 and VA-05, all manufactured by Mitsubishi Chemical Corp.), and calculating the percent water content by dividing the amount of moisture (g) by the sample weight (g).

<Preparation Method>

The composition of the invention can be prepared by mixing the various components described above.

Specifically, in the case of the first embodiment, the composition can be prepared by adding a material for carrier transport to a solvent, mixing them, and then dissolving or dispersing inorganic particles or other optional components in the mixture.

In the case of the second embodiment, the composition can be prepared by adding a material for a thermal excitation source to a solvent, mixing them, and then dissolving or dispersing inorganic particles or other optional components in the mixture.

At this time, in a case in which an electroconductive nanomaterial is used as a material, it is preferable that the various components in the material are such that the electroconductive nanomaterial is in a dispersed state, while other components such as polymer materials are in a dispersed or dissolved state, and it is more preferable that the components except for the electroconductive nanomaterial are in a dissolved state. When the components except for the electroconductive nanomaterial are in a dissolved state, it is preferable because an effect of suppressing the decrease in the electrical conductivity caused by grain boundaries can be obtained.

Meanwhile, the dispersed state is an aggregated state of molecules having a particle size to the extent that no sedimentation occurs in a solvent even if the sample is stored for a long time period (as a reference, one month or longer), and the dissolved state refers to a state in which individual molecules are solvated in a solvent.

There are no particular limitations on the method for producing a thermoelectric conversion material, and the method can be carried out at normal temperature and normal pressure using a conventional mixing apparatus or the like. For example, the thermoelectric conversion material may be produced by stirring, shaking or kneading various components in a solvent, and thereby dissolving or dispersing the components. In order to promote dissolution or dispersion, an ultrasonication treatment may be carried out.

Furthermore, the dispersibility of the electroconductive nanomaterial can be increased by heating the solvent to a temperature that is higher than or equal to room temperature and lower than or equal to the boiling point in the dispersing step, by extending the dispersion time, or by increasing the application intensity of stirring, percolation, kneading, ultrasonication or the like.

[Thermoelectric Conversion Element]

In the following, the thermoelectric conversion element of the invention is described in detail.

The thermoelectric conversion element of the invention is a thermoelectric conversion element having a substrate, a pair of electrodes, and a thermoelectric conversion layer formed from the composition of the invention described above.

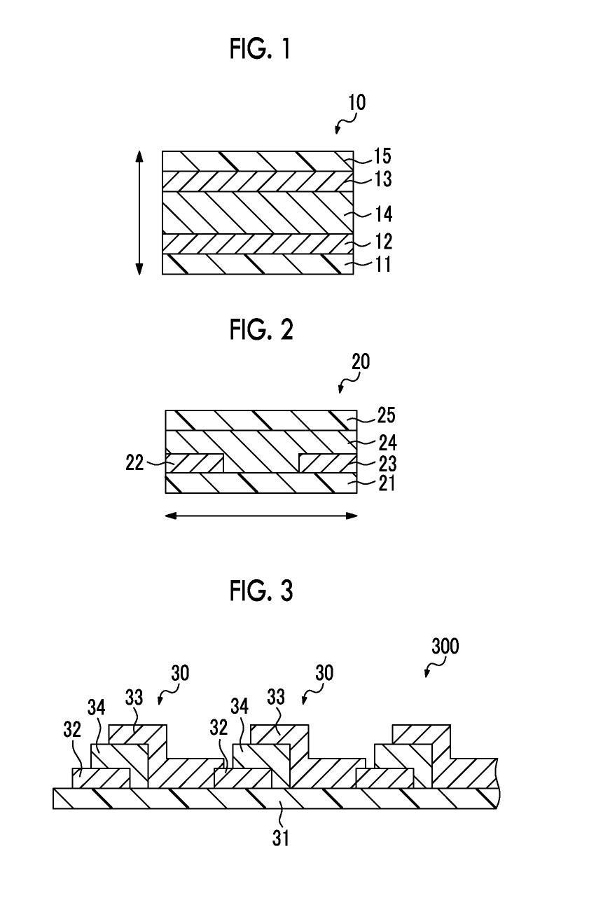

First, the overall configuration of the thermoelectric conversion element of the invention will be explained using FIG. 1 to FIG. 3, which are cross-sectional diagrams schematically illustrating an example of the thermoelectric conversion element of the invention.

The thermoelectric conversion element 10 illustrated in FIG. 1 is an element having a first substrate 11, a first electrode 12, a thermoelectric conversion layer 14 formed from the composition of the invention, a second electrode 13, and a second substrate 15, in this order.

Here, the thermoelectric conversion element 10 illustrated in FIG. 1 corresponds to an embodiment by which an electromotive force (voltage) is obtained by utilizing a temperature difference in the direction indicated by the arrow.

Furthermore, the thermoelectric conversion element 20 illustrated in FIG. 2 is an element having a first electrode 22 and a second electrode 23 on a part of a first substrate 21, and having a thermoelectric conversion layer 24 and a second substrate 25 in this order on the first substrate 21, the first electrode 22, and the second electrode 23.

Here, the thermoelectric conversion element 20 illustrated in FIG. 2 corresponds to an embodiment by which an electromotive force (voltage) is obtained by utilizing a temperature difference in the direction indicated by the arrow.

According to the invention, as illustrated in FIG. 3, a module 300 in which various thermoelectric conversion elements 30 are connected in series may also be produced by using mutually adjoining thermoelectric conversion elements 30 and a common substrate 31, and electrically connecting a second electrode 33 in one thermoelectric conversion element 30 with a first electrode 32 of another thermoelectric conversion element 30 adjacent thereto.

Next, the substrate, electrodes, and thermoelectric conversion layer incorporated in the thermoelectric conversion element of the invention are described in detail.

<Substrate>

The substrate incorporated in the thermoelectric conversion element of the invention is not particularly limited; however, it is preferable to select a substrate which is not easily affected at the time of forming electrodes or at the time of forming a thermoelectric conversion layer.

Examples of such a substrate include glass, transparent ceramics, metals, and plastic films, and among them, a plastic film is preferred from the viewpoints of cost and flexibility.

Specific examples of the plastic film include polyester films such as films of polyethylene terephthalate, polyethylene isophthalate, polyethylene naphthalate, polybutylene terephthalate, poly(1,4-cyclohexylene dimethylene terephthalate), polyethylene-2,6-phthalene dicarboxylate, and a polyester film of bisphenol A with iso- and terephthalic acid; polycycloolefin films such as a ZEONOR film (manufactured by Zeon Corp.), an ARTON film (manufactured by JSR Corp.), and SUMILITE FS1700 (manufactured by Sumitomo Bakelite Co., Ltd.); polyimide films such as KAPTON (manufactured by Du Pont-Toray Co., Ltd.), APICAL (manufactured by Kaneka Corp.), UPILEX (manufactured by Ube Industries, Ltd.), and POMIRAN (manufactured by Arakawa Chemical Industries, Ltd.); polycarbonate films such as PURE-ACE (manufactured by TEIJIN LIMITED) and ELMECH (manufactured by Kaneka Corp.); polyether ether ketone films such as SUMILITE FS1100 (manufactured by Sumitomo Bakelite Co., Ltd.); and polyphenyl sulfide films such as TORELINA (manufactured by Toray Industries, Inc.).

Among these, from the viewpoints of easy availability, heat resistance at or above 100° C., economic efficiency, and effectiveness, commercially available polyethylene terephthalate, polyethylene naphthalate, various polyimides and polycarbonate films, and the like are preferred.

According to the invention, the thickness of the substrate can be appropriately selected according to the purpose of use; however, for example, in the case of using a plastic film, generally, it is preferable to use a substrate having a thickness of 5 μm to 500 μm.

<Electrodes>

The electrodes incorporated in the thermoelectric conversion element of the invention are not particularly limited; however, specific examples of the materials thereof include transparent electrodes of ITO, ZnO and the like; metal electrodes of silver, copper, gold, aluminum and the like; carbon materials such as CNT and graphene; organic materials such as PEDOT/PSS; electroconductive pastes obtained by dispersing electroconductive fine particles of silver, carbon black and the like; and electroconductive pastes containing metal nanowires of silver, copper, aluminum and the like.

<Thermoelectric Conversion Layer>

The thermoelectric conversion layer included in the thermoelectric conversion element of the invention is not particularly limited as long as it is formed from the composition of the invention described above.

The method for forming the thermoelectric conversion layer is not particularly limited; however, the thermoelectric conversion layer can be formed by applying the composition of the invention on the substrate described above, and forming a film.

The film-forming method is not particularly limited, and for example, known coating methods such as spin coating, extrusion die coating, blade coating, bar coating, screen printing, stencil printing, roll coating, curtain coating, spray coating, dip coating, and an inkjet method can be used.

Furthermore, after coating, a drying process is carried out as necessary. For example, the solvent can be volatilized and dried by blowing hot air.

According to the invention, the film thickness of the thermoelectric conversion layer is preferably 0.1 μm to 1,000 μm, and more preferably 1 μm to 100 μm, from the viewpoint of applying a temperature difference.

[Thermoelectric Power Generating Component]

The thermoelectric power generating component of the invention is a thermoelectric power generating component that uses the thermoelectric conversion element of the invention.

Here, specific examples of the thermoelectric power generating component include electric power generators such as a hot spring electrical heat generator, a solar heat power generator, and a waste heat power generator; electric power generation applications such as a power supply for a wrist watch, a semiconductor-driven power supply, and a power supply for a small-sized sensor; and sensor element applications such as a heat-sensitive sensor and a thermocouple.

That is, the thermoelectric conversion element of the invention described above can be suitably used for these applications.

### EXAMPLES

Hereinafter, the present invention will be explained in more detail by way of Examples, but the invention is not intended to be limited to these.

### Example 1

The composition of the first embodiment was prepared, and a thermoelectric conversion element was produced.

<Production of Thermoelectric Conversion Element>

8 mg of an electroconductive polymer [poly-3-hexylthiophene (molecular weight: Mw 20,000), manufactured by Sigma-Aldrich Co. LCC.] and 3 mg of monolayer CNT [ASP-100F, manufactured by Hanwha Nanotech Co., Ltd., dispersion (CNT concentration: 60% by mass), average length of CNT: about 5 μm to 20 μm, average diameter: about 1.0 nm to 1.2 nm] as materials for carrier transport were added to 10 ml of ortho-dichlorobenzene, and the mixture was dispersed for 50 minutes in an ultrasonic water bath. Thus, a dispersion liquid (A) was prepared.

The mobility (cm²/Vs) and the carrier density (cm⁻³) of the materials for carrier transport are presented in the following. Table 1.

On the other hand, powdered raw materials of Bi, Te and Sb were mixed and melted, and a P-type thermoelectric material having a composition of Bi_{0.5}Sb_{1.5}Te₃ was obtained. The material thus obtained was pulverized with a ball mill, and a powder (inorganic particles) was obtained. Meanwhile, the average particle size of the obtained inorganic particles, and the ratio between the number of particles having a particle size of 1.0 μm or less and the number of particles having a particle size of more than 1.0 μm (number of particles having a particle size of 1.0 μm or less/number of particles having a particle size of more than 1.0 μm) were measured using a dynamic light scattering type particle size/particle size distribution analyzer (NANOTRAC UPA-EX150, manufactured by Nikkiso Co., Ltd.). These results are presented in the following Table 1. Furthermore, the band gap of the inorganic particles is presented in the following Table 1.

Next, the dispersion liquid (A) thus prepared and the inorganic particles thus obtained were mixed, and the mixture was mixed using a rotating and revolving mixer (AR-100, manufactured by Thinky Corp.). Thus, a dispersion liquid (B) was prepared.

This dispersion liquid (B) was applied by a stencil printing method on the surface of the electrode 12 side of a polyethylene terephthalate film 11 (thickness: 125 μm) having gold (thickness: 20 nm, width: 5 mm) as a first electrode 12 coated in advance on a single surface (coating step), and the coated film was heated for 30 minutes at 80° C. to remove the solvent (drying step).

These coating step and drying step were repeated, and then the system was dried for 10 hours at room temperature in a vacuum. Thereby, a thermoelectric conversion layer 14 having a film thickness of 1 μm and a size of 8 mm×8 mm was formed.

Thereafter, a polyethylene terephthalate film substrate 15 having gold deposited in advance as a second electrode 13 (thickness of the electrode 13: 20 nm, width of the electrode 13: 5 mm, and thickness of the polyethylene terephthalate film substrate 15: 125 μm) was superimposed on top of the thermoelectric conversion layer 14 at 80° C. such that the second electrode 13 faced the thermoelectric conversion layer 14, and thus a thermoelectric conversion element of the invention, which was the thermoelectric conversion element illustrated in FIG. 1, was produced.

### Examples 2 to 17 and Comparative Examples 1 to 4

Thermoelectric conversion elements were produced in the same manner as in Example 1, except that the kind of the materials for carrier transport (electroconductive nanomaterial and electroconductive polymer material), the presence or absence of a non-conjugated polymer (binder), the presence or absence of dopant 1 represented by the following formula, the average particle size and the ratio of the numbers of particles [(number of particles having a particle size of 1.0 μm or less)/(number of particles having a particle size of more than 1.0 μm)] of the inorganic particles, and the presence or absence of a thermal excitation assisting agent 1 represented by the following formula, were changed as indicated in the following Table 1.

Meanwhile, in Example 10 in which a thermal excitation assisting agent 1 was used, the thermoelectric conversion element was produced in the same manner as in Example 1, except that 2 mg of the thermal excitation assisting agent 1 was added at the time of preparing the dispersion liquid (A). In Example 17 in which the dopant 1 was used, the thermoelectric conversion element was produced in the same manner as in Example 1, except that 5 mg of the dopant 1 was added at the time of preparing the dispersion liquid (A).

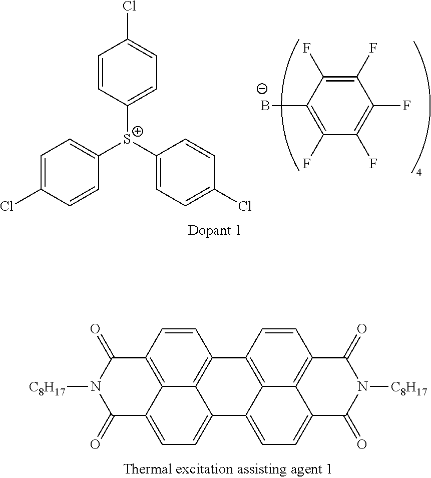

### Example 18

7 mg of TIPS pentacene as a material for carrier transport and 3 mg of a non-conjugated polymer, poly(p-hydroxystyrene), as a binder were added to 10 ml of ortho-dichlorobenzene, and the mixture was stirred for 20 minutes to prepare a solution. Inorganic particles obtained in the same manner as in Example 1 were mixed with the solution in the same manner as in Example 1, and thus a dispersion liquid (C) was prepared.

A thermoelectric conversion element was produced in the same manner as in Example 1, using this dispersion liquid (C).

### Example 19

A thermoelectric conversion element was produced in the same manner as in Example 18, except that 7 mg of benzothienobenzothiophene was used as the material for carrier transport.

### Example 20

A thermoelectric conversion element was produced in the same manner as in Example 1, except that a dispersion liquid (D) was prepared by adding 20 mg of monolayer CNT [ASP-100F, manufactured by Hanwha Nanotech Co., Ltd., dispersion (CNT concentration: 60% by mass), average length of CNT: about 5 μm to 20 μm, and average diameter: about 1.0 nm to 1.2 nm] as a material for carrier transport to 10 ml of ortho-dichlorobenzene, and dispersing the mixture for 50 minutes in an ultrasonic water bath.

### Example 21

A composition of the second embodiment was prepared, and a thermoelectric conversion element was produced.

A metal complex 1 (10 mg) represented by the following formula as a material for a thermal excitation source was added to 10 ml of ortho-dichlorobenzene, and the mixture was stirred for 20 minutes. Thus, a solution was prepared. Silicon carbide particles as inorganic particles were mixed with the solution, and thereby a dispersion liquid (E) was prepared.

A thermoelectric conversion element was produced in the same manner as in Example 1, using this dispersion liquid (E).

### Example 22

A thermoelectric conversion element was produced in the same manner as in Example 21, except that a metal complex 2 represented by the following formula was used as the material for a thermal excitation source, and gallium nitride particles were used as the inorganic particles.

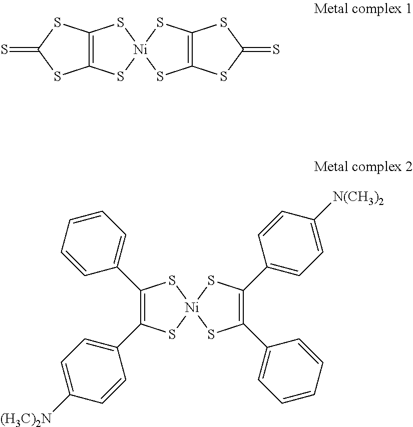

### Comparative Example 5

10 mg of polyacetylene (band gap: 1.4 eV) as a material for carrier transport and a material for a thermal excitation source was added to 10 ml of ortho-dichlorobenzene, and the mixture was dispersed for 20 minutes in an ultrasonic water bath. Thus, a dispersion liquid (F) was prepared. A thermoelectric conversion element was produced in the same manner as in Example 1, using this dispersion liquid (F).

### Comparative Example 6

Inorganic particles (Bi_{0.5}Sb_{1.5}Te₃) produced in the same manner as in Example 1 were used as a material for carrier transport and a material for a thermal excitation source, and the inorganic particles were mixed with a non-conjugated polymer, polystyrene, as a binder. Thus, a dispersion liquid (G) was prepared. A thermoelectric conversion element was produced in the same manner as in Example 1, using this dispersion liquid (G).

For the various thermoelectric conversion elements thus produced, the thermoelectromotive force was evaluated by the method described below.

[Measurement of Thermoelectric Characteristic Value (Thermoelectromotive Force S)]

The first electrode 12 of each thermoelectric conversion element was disposed on a hot plate maintained at a constant temperature, and a Peltier device for temperature control was disposed on the second electrode 13.

While the temperature of the hot plate was maintained constant (100° C.), the temperature of the Peltier device was decreased, and thereby a temperature difference (in the range of more than 0 K but no more than 4 K) was applied between the two electrodes.

At this time, the thermoelectromotive force (μV) generated between the two electrodes was divided by the particular temperature difference (K) generated between the two electrodes, and thereby the thermopower S per unit temperature difference (μV/K) was calculated. This value was designated as the thermoelectric characteristic value of the thermoelectric conversion element.

The thermoelectric characteristic values thus calculated are presented in the following Table 1 and Table 2 as relative values with respect to the calculated value of the thermoelectric conversion element of Example 7.

TABLE 1

| | | | | | | | | | | | | | | | | Evaluation |
|---|---|---|---|---|---|---|---|---|---|---|---|---|---|---|---|---|
| | | | | | | | | | | | | | | | | Thermo- |
| | Inorganic particles | | | | | Material for carrier transport | | | | | | | Other materials | | | electric |
| | | Average | Ratio of | | | Electroconductive nanomaterial | | | Electroconductive polymer material | | | | | | Thermal | charac- |
| | | particle | numbers | Band | | | | Carrier | | | Carrier | Band | Non- | | excitation | teristics |
| | | size | of | gap | Mobility | | Mobility | density | | Mobility | density | gap | conjugated | | assisting | (relative |
| | Material | (μm) | particles* | (eV) | (cm²/Vs) | Material | (cm²/Vs) | (cm⁻³) | Material | (cm²/Vs) | (cm⁻³) | (eV) | polymer | Dopant | agent | value) |
| Example 1 | Bi_{0.5}Sb_{1.5}Te₃ | 0.8 | 7.0 | 0.13 | — | CNT | 30000 | 1 × 10²³ | Poly-3-hexylthiophene | 0.01 | — | — | None | None | None | 276 |
| Example 2 | Bi_{0.5}Sb_{1.5}Te₃ | 0.9 | 7.0 | 0.13 | — | CNT | 30000 | 1 × 10²³ | Poly-3-hexylthiophene | 0.01 | — | — | None | None | None | 281 |
| Example 3 | Bi_{0.5}Sb_{1.5}Te₃ | 1.0 | 7.0 | 0.13 | — | CNT | 30000 | 1 × 10²³ | Poly-3-hexylthiophene | 0.01 | — | — | None | None | None | 278 |
| Example 4 | Bi_{0.5}Sb_{1.5}Te₃ | 0.6 | 7.0 | 0.13 | — | CNT | 30000 | 1 × 10²³ | Poly-3-hexylthiophene | 0.01 | — | — | None | None | None | 286 |
| Example 5 | Bi_{0.5}Sb_{1.5}Te₃ | 0.4 | 7.0 | 0.13 | — | CNT | 30000 | 1 × 10²³3 | Poly-3-hexylthiophene | 0.01 | — | — | None | None | None | 295 |
| Example 6 | Bi_{0.5}Sb_{1.5}Te₃ | 0.8 | 8.0 | 0.13 | — | Graphite | — | 2 × 10²³ | Poly-3-hexylthiophene | 0.01 | — | — | None | None | None | 105 |
| Example 7 | Bi_{0.5}Sb_{1.5}Te₃ | 0.8 | 9.0 | 0.13 | — | Carbon | 0.01 | — | Poly-3-hexylthiophene | 0.01 | — | — | None | None | None | 100 |
| | | | | | | nano- | | | | | | | | | | |
| | | | | | | partiiclcs | | | | | | | | | | |
| Example 8 | Bi_{0.5}Sb_{1.5}Te₃ | 0.8 | 7.0 | 0.13 | — | CNT | 30000 | 1 × 10²³ | — | — | — | — | Polystyrene | None | None | 268 |
| Example 9 | Bi_{0.5}Sb_{1.5}Te₃ | 0.8 | 7.0 | 0.13 | — | CNT | 30000 | 1 × 10²³ | Poly-3-hexylthiophene | 0.01 | — | — | Polystyrene | None | None | 277 |
| Example 10 | Bi_{0.5}Sb_{1.5}Te₃ | 0.8 | 7.0 | 0.13 | — | CNT | 30000 | 1 × 10²³ | Poly-3-hexylthiophene | 0.01 | — | — | None | None | Thermal | 315 |
| | | | | | | | | | | | | | | | excitation | |
| | | | | | | | | | | | | | | | assisting | |
| | | | | | | | | | | | | | | | agent 1 | |
| Example 11 | Bi_{0.5}Sb_{1.5}Te₃ | 0.8 | 5.0 | 0.13 | — | CNT | 30000 | 1 × 10²³ | Poly-3-hexylthiophene | 0.01 | — | — | None | None | None | 271 |
| Example 12 | Bi_{0.5}Sb_{1.5}Te₃ | 0.8 | 4.0 | 0.13 | — | CNT | 30000 | 1 × 10²³ | Poly-3-hexylthiophene | 0.01 | — | — | None | None | None | 203 |
| Example 13 | Bi_{0.5}Sb_{1.5}Te₃ | 0.8 | 2.0 | 0.13 | — | CNT | 30000 | 1 × 10²³ | Poly-3-hexylthiophene | 0.01 | — | — | None | None | None | 187 |
| Example 14 | Bi_{0.5}Sb_{1.5}Te₃ | 0.8 | 20.0 | 0.13 | — | CNT | 30000 | 1 × 10²³ | Poly-3-hexylthiophene | 0.01 | — | — | None | None | None | 279 |
| Example 15 | Bi_{0.5}Sb_{1.5}Te₃ | 0.8 | 50.0 | 0.13 | — | CNT | 30000 | 1 × 10²³ | Poly-3-hexylthiophene | 0.01 | — | — | None | None | None | 281 |
| Example 16 | Bi_{0.5}Sb_{1.5}Te₃ | 0.8 | 100.0 | 0.13 | — | CNT | 30000 | 1 × 10²³ | Poly-3-hexylthiophene | 0.01 | — | — | None | None | None | 287 |
| Example 17 | Bi_{0.5}Sb_{1.5}Te₃ | 0.8 | 7.0 | 0.13 | — | CNT | 30000 | 1 × 10²³ | Poly-3-hexylthiophene | 0.01 | — | — | None | Dopant 1 | None | 298 |
| Example 18 | Bi_{0.5}Sb_{1.5}Te₃ | 0.8 | 7.0 | 0.13 | — | — | — | — | TIPS pentacene | 0.5 | — | — | Poly(p- | None | None | 130 |
| | | | | | | | | | | | | | hydroxy- | | | |
| | | | | | | | | | | | | | styrene) | | | |
| Example 19 | Bi_{0.5}Sb_{1.5}Te₃ | 0.8 | 7.0 | 0.13 | — | — | — | — | Benzothieno- | 0.1 | — | — | Poly(p- | None | None | 140 |
| | | | | | | | | | benzothiophene | | | | hydroxy- | | | |
| | | | | | | | | | | | | | styrene) | | | |
| Example 20 | Bi_{0.5}Sb_{1.5}Te₃ | 0.8 | 7.0 | 0.13 | — | CNT | 30000 | 1 × 10²³ | — | — | — | — | None | None | None | 238 |
| Comparative | Bi_{0.5}Sb_{1.5}Te₃ | 1.1 | 3.0 | 0.13 | — | CNT | 30000 | 1 × 10²³ | Poly-3-hexylthiophene | 0.01 | — | — | None | None | None | 12 |
| Example 1 | | | | | | | | | | | | | | | | |
| Comparative | Bi_{0.5}Sb_{1.5}Te₃ | 2.0 | 2.0 | 0.13 | — | CNT | 30000 | 1 × 10²³ | Poly-3-hexylthiophenc | 0.01 | — | — | None | None | None | 14 |
| Example 2 | | | | | | | | | | | | | | | | |
| Comparative | Bi_{0.5}Sb_{1.5}Te₃ | 20.0 | 0.1 | 0.13 | — | CNT | 30000 | 1 × 10²³ | Poly-3-hexylthiophene | 0.01 | — | — | None | None | None | 11 |
| Example 3 | | | | | | | | | | | | | | | | |
| Comparative | Bi_{0.5}Sb_{1.5}Te₃ | 200.0 | 0.003 | 0.13 | — | CNT | 30000 | 1 × 10²³ | Poly-3-hexylthiophene | 0.01 | — | — | None | None | None | 15 |
| Example 4 | | | | | | | | | | | | | | | | |
| Comparative | — | — | — | — | — | — | — | — | Polyacetylene | 0.8 | — | 1.4 | None | None | None | 10 or less |
| Example 5 | | | | | | | | | | | | | | | | |
| Comparative | Bi_{0.5}Sb_{1.5}Te₃ | 0.8 | 7.0 | 0.13 | 1200 | — | — | — | — | — | — | — | Polystyrene | None | None | 10 or less |
| Example 6 | | | | | | | | | | | | | | | | |

*Ratio of numbers of particles = (Number of particles having a particle size of 1.0 μm or less)/(number of particles having a particle size of more than 1.0 μm)

TABLE 2

| | Inorganic particles | | | | | Material for thermal | | | Other materials | | | |
|---|---|---|---|---|---|---|---|---|---|---|---|---|
| | | Average | | | | excitation source | | | | | Thermal | Evaluation |
| | | particle | Ratio of | Band | | | Band | | Non- | | excitation | Thermoelectric |
| | | size | numbers of | gap | Mobility | | gap | Mobility | conjugated | Dop- | assisting | characteristics |
| | Material | (μm) | particles * | (eV) | (cm²/Vs) | Material | (eV) | (cm²/Vs) | polymer | ant | agent | (relative value) |
| Example 21 | SiC | 0.8 | 7.5 | 3.2 | 1000 | Metal | 0.7 | — | None | None | None | 276 |
| | | | | | | complex 1 | | | | | | |
| Example 22 | GaN | 0.9 | 7.0 | 3.4 | 200 | Metal | 0.9 | — | None | None | None | 281 |
| | | | | | | complex 9 | | | | | | |
| Comparative | — | — | — | — | — | Poly- | 1.4 | 0.8 | None | None | None | 10 or less |
| Example 5 | | | | | | acetylene | | | | | | |
| Comparative | Bi_{0.5}Sb_{1.5}Te₃ | 0.8 | 7.0 | 0.13 | 1200 | — | — | — | Poly- | None | None | 10 or less |
| Example 6 | | | | | | | | | styrene | | | |

* Ratio of numbers of particles = (Number of particles having a particle size of 1.0 μm or less)/(number of particles having a particle size of more than 1.0 μm)

From the results shown in Table 1 and Table 2, it was found that a thermoelectric conversion element produced using a composition which includes inorganic particles having an average particle size of 1.0 μm or less, and is obtained by combining the inorganic particles with a material appropriate for the band gap of the inorganic particles, has markedly enhanced thermoelectric performance, compared to thermoelectric conversion elements produced using compositions that include inorganic particles having an average particle size of more than 1.0 μm.

Furthermore, from a comparison of Examples 1 to 7, it was found that when carbon nanotubes are used as an electroconductive nanomaterial, more satisfactory thermoelectric characteristics are obtained.

Furthermore, from a comparison of Examples 1 and 11 with Examples 12 and 13, it was found that when a composition in which the ratio of the number of particles of the inorganic particles is 5 or more is used, more satisfactory thermoelectric characteristic values are obtained.

Furthermore, from a comparison of Example 1 with Examples 18 to 20, it was found that it is preferable to incorporate electroconductive nanoparticles and an electroconductive polymer as the material for carrier transport.

### EXPLANATION OF REFERENCES

10, 20, 30: Thermoelectric conversion element
11, 21: First substrate
12, 22, 32: First electrode
13, 23, 33: Second electrode
14, 24, 34: Thermoelectric conversion layer
15, 25: Second substrate
31: Substrate
300: Module

What is claimed is:

1. A composition for Ruining a thermoelectric conversion layer, the composition comprising:
inorganic particles having an average particle size of 1.0 μm or less and a band gap of 1.5 eV or less; and
a material for carrier transport which satisfies at least one of the condition that the mobility is 0.001 cm²/Vs or more and the condition that the carrier density is 1×10¹⁰ cm⁻³ to 1×10²¹ cm⁻³,
wherein the material for carrier transport includes both an electroconductive nanomaterial and an electroconductive polymer material.

2. The composition for forming a thermoelectric conversion layer according to claim 1, wherein the electroconductive nanomaterial is a carbon nanomaterial or a metal nanomaterial.

3. The composition for forming a thermoelectric conversion layer according to claim 1, wherein the electroconductive nanomaterial is at least one selected from the group consisting of carbon nanotubes, carbon nanofibers, graphite, graphene, carbon nanoparticles, and metal nanowires.

4. The composition for forming a thermoelectric conversion layer according claim 1, wherein the electroconductive nanomaterial is the carbon nanotubes.

5. The composition for forming a thermoelectric conversion layer according to claim 1, wherein the material for carrier transport is an organic material.

6. A composition for forming a thermoelectric conversion layer, the composition comprising:
inorganic particles having an average particle size of 1.0 μm or less and a band gap of more than 1.5 eV; and
a material for a thermal excitation source which is an organic material satisfying the condition that a band gap is 1.5 eV or less,
wherein the material for a thermal excitation source includes at least one selected from the group consisting of a carbon nanomaterial, an infrared absorbing dye, and an electroconductive polymer.

7. The composition for forming a thermoelectric conversion layer according to claim 6, wherein the electroconductive polymer is polythiophene or polyacetylene.

8. The composition for forming a thermoelectric conversion layer according to claim wherein the ratio between the number of particles having a particle size of 1.0 μm or less and the number of particles having a particle size of more than 1.0 μm (number of particles having a particle size of 1.0 μm or less/number of particles having a particle size of more than 1.0 μm) in the inorganic particles is 5 or more.

9. The composition for forming a thermoelectric conversion layer according to claim 6, wherein the ratio between the number of particles having a particle size of 1.0 μm or less and the number of particles having a particle size of more than 1.0 μm (number of particles having a particle size of 1.0 μm or less/number of particles having a particle size of more than 1.0 μm) in the inorganic particles is 5 or more.

10. The composition for forming a thermoelectric conversion layer according to claim 1, further comprising a dopant.

11. The composition for forming a thermoelectric conversion layer according to claim 6, further comprising a dopant.

12. The composition for forming a thermoelectric conversion layer according to claim 1, further comprising a non-conjugated polymer.

13. The composition for forming a thermoelectric conversion layer according to claim 6, further comprising a non-conjugated polymer.

14. A thermoelectric conversion element comprising:
a substrate;
a pair of electrodes; and
a thermoelectric conversion layer,
wherein the thermoelectric conversion layer is formed from the composition for forming a thermoelectric conversion layer according to claim 1.

15. A thermoelectric conversion element comprising:
a substrate;
a pair of electrodes; and
a thermoelectric conversion layer,
wherein the thermoelectric conversion layer is formed from the composition for forming a thermoelectric conversion layer according to claim 6.

16. A thermoelectric power generating component, using the thermoelectric conversion element according to claim 14.

17. A thermoelectric power generating component, using the thermoelectric conversion element according to claim 15.
